(19) United States
(12) Patent Application Publication
(10) Pub. No.: US 2025/0316447 A1
(43) Pub. Date: Oct. 9, 2025

(54) RIBBON BEAM UNIFORMITY TUNING USING MACHINE LEARNING

(71) Applicant: Applied Materials, Inc., Santa Clara, CA (US)

(72) Inventor: Christopher Ilic LANG, Boston, MA (US)

(73) Assignee: Applied Materials, Inc., Santa Clara, CA (US)

(21) Appl. No.: 18/625,828

(22) Filed: Apr. 3, 2024

(51) Int. Cl. H01J 37/304; H01J 37/317

(52) U.S. Cl. CPC H01J 37/304; H01J 37/3171; H01J 2237/24507

(57) ABSTRACT

Techniques for ribbon beam tuning segment tuning using machine learning are described. A method comprises receiving a set of control parameters representing configurations of multiple tuning segments of a tuning assembly for an ion implanter, predicting a set of process parameters representing one or more metrics associated with a beam property for an ion beam generated by the ion implanter based on the configurations of the multiple tuning segments using a control model, the control model comprising a forward model using a tuning matrix generated from a set of observations and a covariance matrix, and configuring a set of configurations for the multiple tuning segments based on the set of process parameters, the set of configurations for the multiple tuning segments to cause the ion beam to match a target metric for the ion beam. Other embodiments are described and claimed.

### BACKGROUND

An ion implanter is a device used in the semiconductor industry for doping or modifying the properties of materials. It is specifically designed to precisely introduce impurities, known as dopants, into target material to create semiconductor devices like transistors. The target material is usually a silicon wafer. The process involves accelerating ions to high speeds using an electric field and directing them towards the target material. The accelerated ions penetrate a substrate of the target material, displacing atoms and creating a controlled distribution of dopants in the substrate. The ion implanter typically comprises various components, such as an ion source to generate the desired ions, an accelerator to increase their energy, a mass analyzer to select the desired ions, and a beamline system to direct and focus the ion beam onto the substrate. The implanter settings, such as energy and current, are carefully controlled to achieve the desired dopant depth and concentration profiles. By precisely controlling the ion energy and dose, an ion implanter allows the customization of material properties. It plays a crucial role in the fabrication of integrated circuits, where different dopants create various regions necessary for device functionality, such as transistor gates, source, and drain regions. Overall, an ion implanter is a vital tool in the semiconductor industry for precisely introducing controlled impurities into materials, enabling the creation of advanced electronic devices.

A series of electrodes are regulated at particular voltages with respect to ground to extract ions from the ion source chamber. For ribbon beams each of the electrodes include a slot having a particular length to extract the ions into a beam for downstream wafer implantation. When an ion beam is extracted, variations in beam related characteristics, such as contaminants, pressure, temperature, beam drift etc. influence beam uniformity. For example, beam non-uniformities may be caused by various electrode characteristics. Ideally, a current density of the beam components remains constant about a defined point. The disparity in uniformity along the length of the electrode slot compromises the uniformity of the beam at wafer implantation. Prior attempts to correct for these non-uniformities include providing a segmented electrode with conducting sections and insulating sections. The insulating sections are used to prevent interference between the electrode sections. Another attempt at correcting for these non-uniformities included providing a plurality of insulating rings surrounding a corresponding tuning segment. Actuators are used to displace only the insulating ring portions perpendicular to the tuning segments to control the power delivered to each tuning segment. However, these prior attempts have not sufficiently corrected the non-uniformities resulting from extraction of an ion beam from an ion source chamber. In addition, corrector magnet rods and poles may also be employed in ion implanters to provide beam uniformity tuning. However, this may require long tune times for certain desired beam profile features.

Conventional tuning techniques are slow and often require a large number of iterations in order to converge, and still do not select globally optimal tuning segment locations. Excess tuning time reduces throughput of tools, as retuning is often required when a recipe is changed. Additionally, sub-optimal tuning segment locations could result in sub-optimal ribbon beam uniformity. Thus, there is a need to improve these and other technical challenges.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates an ion implanter in accordance with one embodiment.

FIG. 2 illustrates an ion implanter in accordance with one embodiment.

FIG. 3A illustrates an electrode assembly in accordance with one embodiment.

FIG. 3B illustrates an electrode assembly in accordance with one embodiment.

FIG. 4 illustrates a corrector-bar assembly in accordance with one embodiment.

FIG. 5 illustrates a set of displacement profiles in accordance with one embodiment.

FIG. 6A illustrates a displacement matrix in accordance with one embodiment.

FIG. 6B illustrates a displacement profile in accordance with one embodiment.

FIG. 7 illustrates a machine learning (ML) system in accordance with one embodiment.

FIG. 8 illustrates a displacement matrix in accordance with one embodiment.

FIG. 9 illustrates a correlation structure for a particular model coefficient in accordance with one embodiment.

FIG. 10 illustrates a set of matrices in accordance with one embodiment.

FIG. 11 illustrates correlation coefficients in accordance with one embodiment.

FIG. 12 illustrates measurements used for model calibration, which generates initial estimates for the displacement profiles and corresponding covariance matrices, and their locations in accordance with one embodiment

FIG. 13 illustrates a ML system in accordance with one embodiment.

FIG. 14 illustrates an aspect of the subject matter in accordance with one embodiment.

FIG. 15 illustrates an aspect of the subject matter in accordance with one embodiment.

FIG. 16 illustrates a logic flow in accordance with one embodiment.

FIG. 17 illustrates an inferencing system in accordance with one embodiment.

FIG. 18 illustrates a training device in accordance with one embodiment.

FIG. 19 illustrates a training system in accordance with one embodiment.

FIG. 20 illustrates computer readable medium (CRM) in accordance with one embodiment.

FIG. 21 illustrates a computing system in accordance with one embodiment.

### DETAILED DESCRIPTION

Embodiments are generally directed to artificial intelligence (AI) and machine learning (ML) techniques for controlling a configuration or operation of an ion implanter. Some embodiments are particularly directed to ML techniques for rapidly selecting a configuration or arrangement for tuning segments (e.g., electrodes, rods, coils, poles, etc.) of a tuning assembly to optimize ribbon beam angles and dose uniformity. Embodiments offer a time-efficient, iterative optimization technique which both models the effect of changing tuning segment configurations (e.g., position for rods, current for coils, voltage for poles, etc.) on beam dose and angles, and uses this model to select new, optimal, tuning segment configurations. A forward model uses a Bayesian fitting technique, with a physics informed prior belief that updates its belief on every iteration. The forward model is used to select new tuning segment configurations while also reducing the effect of potential overfitting.

Ion implantation is a process used to dope ions into a work piece. One type of ion implantation is used to implant impurity ions during the manufacture of semiconductor substrates to obtain desired electrical device characteristics. An ion implanter generally includes an ion source chamber which generates ions of a particular species, a beamline system comprising a series of beamline components to control the ion beam, and a platen to secure a silicon wafer that receives the ion beam. These components are housed in a vacuum environment to prevent contamination and dispersion of the ion beam. The beam line components may include a series of electrodes to extract the ions from the source chamber, a mass analyzer configured with a particular magnetic field such that only the ions with a desired mass-to-charge ratio are able to travel through the analyzer, and a corrector magnet to provide a ribbon beam which is directed to a wafer orthogonally with respect to the ion beam to implant the ions into the wafer substrate. The ions lose energy when they collide with electrons and nuclei in the substrate and come to rest at a desired depth within the substrate based on the acceleration energy. The depth of implantation into the substrate is based on the ion implant energy and the mass of the ions generated in the source chamber. Typically, arsenic or phosphorus may be doped to form n-type regions in the substrate and boron, gallium or indium are doped to create p-type regions in the substrate.

There is a need to provide a beam profile pre-tuning method utilizing an electrode configuration which is capable of extracting an ion ribbon beam having a uniform beam profile for wafer implantation. To solve these and other challenges, embodiments are generally directed to techniques to control a tuning assembly for an ion implanter. In various embodiments, a tuning assembly is used with an ion source chamber. In one embodiment, for example, the tuning assembly comprises an electrode having a slot with length L for extracting an ion beam. The electrode is partitioned into a plurality of tuning segments defined at least within the length L of the extraction slot of the electrode. Each of the tuning segments is configured to affect an ion ribbon beam, such as perturbing local parts of the ion ribbon beam, deflecting a beamlet of the ion ribbon beam, or even blocking beamlets of the ion ribbon beam. The configurations of the tuning segments of the tuning assembly changes one or more properties of the ion beam extracted from the ion source chamber changes a current density profile for the ion beam. For example, a controller may change a configuration for at least one of the tuning segments to modify the current density of a portion of the ion beam corresponding to the configuration of the tuning segment to provide a more uniform current density ion beam profile.

In one embodiment, for example, the tuning assembly may comprise an electrode assembly and the tuning segments may be rods. The rods may be displaced (e.g., change in position) in at least one direction (e.g., a y-axis) with respect to the ion beam extracted from the ion source chamber to deflect at least one beamlet of the ion ribbon beam. In this case, a plurality of actuators are connected to the plurality of tuning segments for displacing one or more of the tuning segments.

In one embodiment, for example, the tuning assembly may comprise a corrector-bar assembly comprising a set of magnetic core members and the tuning segments may be a set of coils distributed along the set of magnetic core members. Each of the coils may be individually excited to different current levels to deflect at least one beamlet of the ion ribbon beam.

In one embodiment, for example, the tuning assembly may comprise an electrode assembly and the tuning elements may comprise a set of “poles” or small electrodes. Each of the poles or small electrodes can be powered to different voltage levels to deflect at least one beamlet of the ion ribbon beam.

In various embodiments, a control system may control settings for different components of an ion implanter. In one embodiment, for example, the control system is arranged to control one or more tuning segments of a tuning assembly to modify or adjust a current density for a portion of the ion beam to create a more uniform beam profile. In some embodiments, the control system uses one or more ML models to assist in controlling the tuning assembly. For example, the control system may implement a forward model to predict various parameters for the ion implanter, such as control parameters, process parameters, and so forth. A control parameter corresponds to a hardware or software setting for a component of the ion implanter. A process parameter correspond to metrology for a beam property of an ion beam generated by the ion implanter. In one embodiment, for example, the forward model is a control model arranged to predict process parameters from control parameters. In one embodiment, for example, the forward model is an inverted control model arranged to select control parameters given process parameters. It may be appreciated that the ML model may be designed for many types of control parameters and process parameters for the ion implanter using the principles described herein. Embodiments are not limited in this context.

In one embodiment, for example, the ML model is a control model arranged as a forward model to receive as input a set of control parameters for the tuning assembly of the ion implanter and predict a set of process parameters for the ion beam. For example, the set of control parameters may represent configurations of one or more of the tuning segments (e.g., rods) disrupting portions of a ribbon ion beam, and the set of process parameters may represent a current density and/or an implant angle for the ribbon ion beam to deliver ions to a wafer at an end station. The control model is trained to predict horizontal angles and dose profiles based on tuning segment configurations. It is a linear (affine) model between tuning segment configurations and corresponding metrics. Each tuning segment has a unique (learned) displacement profile which represents dose changes across a wafer when adjusting one or more rods. A displacement profile for each tuning segment is generated and stored in a displacement matrix. A similar matrix is generated and stored in an angle matrix for the angle responses. In one embodiment, a covariance matrix corresponding to the displacement matrix and/or angle matrix may be used to accelerate training of the control model. The covariance matrix may include, for example, a correlation structure such as a correlation matrix comprising one or more correlation slices.

In one embodiment, for example, the ML model is an inverted control model arranged as a forward model to receive as input a set of process parameters for the ion beam and predict a set of control parameters for the tuning assembly of the ion implanter. For example, the set of process parameters may comprise a current density and/or an implant angle for a ribbon ion beam, and the set of control parameters may comprise configurations of one or more of the tuning segments disrupting portions of the ribbon ion beam. Once the displacement matrix and/or angle matrix are populated with a suitable number of observations or samples (e.g., trained), the inverted control model may use the displacement matrix and the angle matrix to predict control parameters from process parameters.

In various embodiments, the ML model is implemented as a Bayesian model using Bayesian statistics. Bayesian models are useful in machine learning because they provide a systematic framework for updating beliefs in the presence of uncertainty and can also give a measure of uncertainty in model predictions. In one embodiment, for example, the ML model is implemented as, or similar to, a Bayesian Linear Regression model. Other ML models may be used as well. Embodiments are not limited to this example.

Embodiments solve various technical challenges faced by conventional techniques. For example, embodiments do not assume any closed form approximation of the effects of changing tuning segment configurations. In another example, embodiments update beliefs with new observations, allowing the model to update during tuning. In yet another example, a prior belief for the model is biased in order to favor more likely solutions and to prevent overfitting.

Embodiments provide several benefits or advantages relative to previous approaches or solutions. For example, the model converges faster, reducing uniformity tuning time, and thus improving throughput. In another example, the model results in more uniform implants compared to existing techniques. In yet another example, the model is programmable, allowing implementation of solutions with better dose uniformity, or angle uniformity, depending on application requirements. Other benefits and advantages exist as well.

The present disclosure will now be described with reference to the attached drawing figures, wherein like reference numerals are used to refer to like elements throughout, and wherein the illustrated structures and devices are not necessarily drawn to scale. As utilized herein, terms “component,” “system,” “interface,” and the like are intended to refer to a computer-related entity, hardware, software (e.g., in execution), and/or firmware. For example, a component can be a processor (e.g., a microprocessor, a controller, or other processing device), a process running on a processor, a controller, an object, an executable, a program, a storage device, a computer, a tablet PC and/or a user equipment (e.g., mobile phone, etc.) with a processing device. By way of illustration, an application running on a server and the server can also be a component. One or more components can reside within a process, and a component can be localized on one computer and/or distributed between two or more computers. A set of elements or a set of other components can be described herein, in which the term “set” can be interpreted as “one or more.”

Further, these components can execute from various computer readable storage media having various data structures stored thereon such as with a module, for example. The components can communicate via local and/or remote processes such as in accordance with a signal having one or more data packets (e.g., data from one component interacting with another component in a local system, distributed system, and/or across a network, such as, the Internet, a local area network, a wide area network, or similar network with other systems via the signal).

As another example, a component can be an apparatus with specific functionality provided by mechanical parts operated by electric or electronic circuitry, in which the electric or electronic circuitry can be operated by a software application or a firmware application executed by one or more processors. The one or more processors can be internal or external to the apparatus and can execute at least a part of the software or firmware application. As yet another example, a component can be an apparatus that provides specific functionality through electronic components without mechanical parts; the electronic components can include one or more processors therein to execute software and/or firmware that confer(s), at least in part, the functionality of the electronic components.

Use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form. Furthermore, to the extent that the terms “including”, “includes”, “having”, “has”, “with”, or variants thereof are used in either the detailed description or the claims, such terms are intended to be inclusive in a manner similar to the term “comprising.” Additionally, in situations wherein one or more numbered items are discussed (e.g., a “first X”, a “second X”, etc.), in general the one or more numbered items may be distinct or they may be the same, although in some situations the context may indicate that they are distinct or that they are the same.

As used herein, the term “circuitry” may refer to, be part of, or include a circuit, an integrated circuit (IC), a monolithic IC, a discrete circuit, a hybrid integrated circuit (HIC), an Application Specific Integrated Circuit (ASIC), an electronic circuit, a logic circuit, a microcircuit, a hybrid circuit, a microchip, a chip, a chiplet, a chipset, a multi-chip module (MCM), a semiconductor die, a system on a chip (SoC), a processor (shared, dedicated, or group), a processor circuit, a processing circuit, or associated memory (shared, dedicated, or group) operably coupled to the circuitry that execute one or more software or firmware programs, a combinational logic circuit, or other suitable hardware components that provide the described functionality. In some embodiments, the circuitry may be implemented in, or functions associated with the circuitry may be implemented by, one or more software or firmware modules. In some embodiments, circuitry may include logic, at least partially operable in hardware.

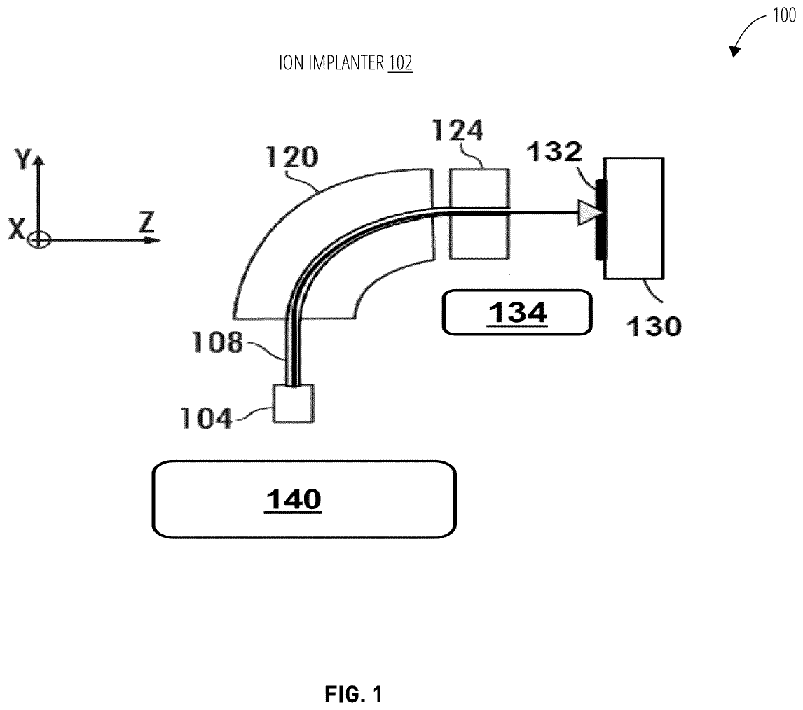

FIG. 1 depicts a schematic view of a system 100 including an ion implanter 102, in accordance with embodiments of the disclosure. The ion implanter 102 may include an ion source 104 for producing an ion beam 108, and a series of beam-line components. The ion source 104 may comprise a chamber for receiving a flow of gas and generating ions. The ion source 104 may also comprise a power source and an extraction electrode assembly (not shown) disposed near the chamber.

Suitable ions for ion beam 108 may include any ion species at a suitable ion energy, including ions such as phosphorous, boron, argon, indium, BF₂, nitrogen, oxygen, hydrogen, inert gas ions, and metallic ions, according to some non-limiting embodiments, with ion energy being tailored according to the exact ion species used.

The beam-line components may include, for example, a mass analyzer 120, and an end station 130, to house and manipulate a substrate 132 that is to intercept the ion beam 108. Thus, the ion source 104, as well as additional beamline components, will provide the ion beam 108 to the substrate 132, having a suitable ion species, ion energy, beam size, and beam angle, among other features, for implanting ions into the substrate 132.

In FIG. 1, in addition to a mass analyzer, according to various non-limiting embodiments, additional components that lie downstream to the ion source 104 may be included. These additional components may include components to accelerate ion beam 108, decelerate ion beam 108, focus ion beam 108, steer ion beam 108, collimate ion beam 108, mass filter ion beam 108, and scan ion beam 108, among other operations. Examples of components to accelerate an ion beam 108 include a DC accelerator column, an RF linear accelerator, and a tandem accelerator, as known in the art. Examples of components to scan the ion beam 108 include an electrostatic scanner or a magnetic scanner. An example of a component to focus the ion beam 108 includes a quadrupole lens.

The ion implanter 102 may further include one or more measurement components, arranged at one or more locations along the beam-line, between ion source 104 and end station 130. For simplicity, these components are shown as beam measurement component 134. Examples of measurement component 134 include ion beam current measurement devices, ion beam angle measurement devices, ion beam energy measurement devices, and ion beam size measurement devices. In one example, the beam measurement component 134 may be a current detector such as a scanning detector, a closed loop current detector, and in particular a closed loop Faraday current detector (CLF), for monitoring beam current provided to the substrate 116. The beam measurement component may be disposed to intercept the ion beam 108 and may be configured to record beam current of the ion beam 108, either at a fixed configuration, or as a function of configuration. In some examples, the beam current of ion beam 108 may be measured for a region of interest (ROI), such as the region of the substrate 116.

The ion implanter 102 may also include a control system 140, which system may be included as part of ion implanter 102, to control operations such as adjustments to ion beam parameters. These parameters may include ion beam energy, ion beam size, ion beam current, ion beam angle, and so forth. In turn, the control system 140 may adjust and control these parameters by adjusting the operation of various components of the aforementioned beamline components of the ion implanter 140. The control system 140 may be included in the ion implanter 102 or may be coupled to the ion implanter 102 in order to implement the AI and ML techniques for automatically tuning one or more components of the ion implanter 102 as set forth in the embodiments to follow.

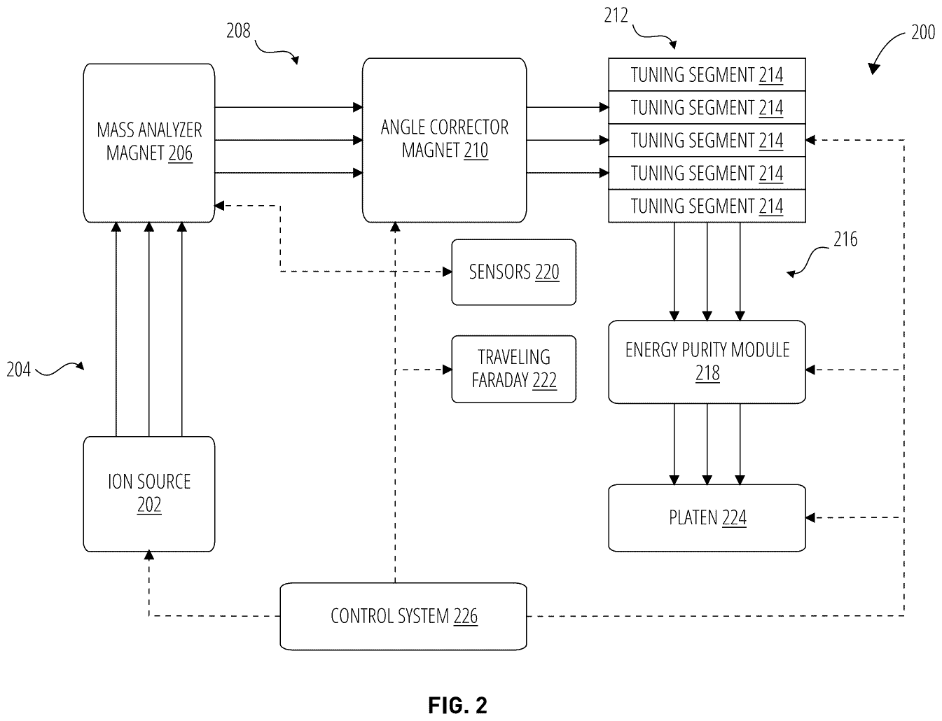

FIG. 2 depicts an ion implanter 200. The ion implanter 200 is an example of a high current ribbon beam ion implanter in accordance with various additional embodiments of the disclosure.

As depicted in FIG. 2, the ion implanter 200 includes an ion source 202 configured to generate an ion ribbon beam 204. Suitable ions for ion ribbon beam 204 may include any ion species at a suitable ion energy, including ions such as phosphorous, boron, argon, indium, BF₂, nitrogen, oxygen, hydrogen, inert gas ions, and metallic ions, according to some non-limiting embodiments, with ion energy being tailored according to the exact ion species used.

The ion implanter 200 may comprise a number of beamline components to process the ion ribbon beam 204. For example, a mass analyzer magnet 206 receives the ion ribbon beam 204 with all ions from the ion source 202 and filters it to obtain desired ions to form a diverged ion beam 208. Desired ions follow a particular path and are bent a desired angle. Undesired ions are bent too much or not enough and get filtered out of the ion ribbon beam 204. An angle corrector magnet 210 receives the diverged ion beam 208 and bends it for parallel ion trajectories at the exit. Note the angle corrector magnet 210 and mass analyzer magnet 206 are shown with top pole piece removed so the ion beam is visible. The ion implanter 200 may further include other beamline components which are omitted for clarity, such as electrodes, magnets, actuators, energy sources, and so forth. Embodiments are not limited to a particular set of beamline components.

The ion implanter 200 further includes a tuning assembly 212 for placement among the beamline components (e.g., electrodes, magnets, sensors, etc.) between the ion source 202 and a platen 224. In one embodiment, for example, the tuning assembly 212 is embedded within the angle corrector magnet 210 or positioned near an exit for the angle corrector magnet 210 that generates a magnetic field.

The tuning assembly 212 may be configured to correct current density non-uniformities in an ion ribbon beam 204, such as the diverged ion beam 208. Specifically, the tuning assembly 212 is a physical component that is arranged to tune an ion ribbon beam 204 to produce a uniform beam profile for wafer implantation by the ion implanter 200. In one embodiment, for example, the tuning assembly 212 comprises a plurality of tuning segments 214. Each tuning segment 214 is individually or collectively configured to affect the diverged ion beam 208, such as perturbing local parts of the diverged ion beam 208, deflecting a beamlet of the diverged ion beam 208, or even blocking beamlets of the diverged ion beam 208. Certain configurations of the tuning segments 214 of the tuning assembly 212 change one or more properties of the diverged ion beam 208, which in turn changes a current density profile for the diverged ion beam 208, thereby forming a perturbed ion beam 216. For example, a control system 226 may change a configuration for a tuning segment 214 to modify the current density of a portion of the diverged ion beam 208 corresponding to the configuration of the tuning segment 214 to provide a more uniform current density ion beam profile for the perturbed ion beam 216.

FIG. 2 depicts the tuning assembly 212 as an electrode assembly and the tuning segment 214 as a plurality of rods as represented as circular openings of the tuning assembly 212. The rods may be displaced (e.g., change in position) in at least one direction (e.g., a y-axis) with respect to the diverged ion beam 208 (e.g., a z-axis) to deflect at least one beamlet of the diverged ion beam 208. In this case, a plurality of actuators (not shown) are connected to the plurality of tuning segments for displacing one or more of the tuning segments.

In other embodiments, the tuning assembly 212 may be implemented using other techniques. In one embodiment, for example, the tuning assembly 212 may comprise a corrector-bar assembly comprising a set of magnetic core members and the tuning segments may be a set of coils distributed along the set of magnetic core members. Each of the coils may be individually excited to different current levels to deflect at least one beamlet of the diverged ion beam 208. In one embodiment, for example, the tuning assembly 212 may comprise an electrode assembly and the tuning elements may comprise a set of “poles” or small electrodes. Each of the poles or small electrodes can be powered to different voltage levels to deflect at least one beamlet of the diverged ion beam 208. Other types of tuning assembly 212 may be implemented to form the perturbed ion beam 216. Embodiments are not limited to these examples.

The tuning assembly 212 includes a set of vertical tuning segments 308 that are configuration above and/or below the diverged ion beam 208. In one embodiment, the vertical tuning segments 308 are magnetic rods. In one embodiment, the magnetic rods are steel magnetic rods. A vertical configuration of each of the magnetic rods adjust current density at the end of beamline via a changing magnetic field.

In one embodiment, for example, the tuning assembly 212 may be disposed as part of an electrode configuration (not shown) or in proximity to an electrode configuration. Examples of electrodes include without limitation a plasma electrode, a suppression electrode, a ground electrode, and so forth. These electrodes are used to create a desired electric field to focus ion ribbon beam 204 extracted from ion source 202. The plasma electrode includes a slot through which ions extracted from ion source 202 pass. The plasma electrode may be biased at the same large potential as the ion source 202. The slot has a length that is significantly greater than its width to provide a high aspect ratio to form a ribbon ion beam. At high aspect ratios, the gas flow from the source is reduced which allows ion source 202 to function at higher plasma densities. Similarly, a suppression electrode includes a slot aligned with the slot of the plasma electrode, which has a length significantly greater than its width. The suppression electrode is connected to a power supply and is typically biased at a moderate negative value to prevent electrons from entering back into ion source 202 and to assist in focusing ion ribbon beam 204. A ground electrode is positioned downstream from suppression electrode and is at ground potential. The ground electrode includes slot aligned with the slots of plasma electrode and suppression electrode which also has a length significantly greater than its width. The strength of the electric field generated by the electrodes can be tuned to a desired beam current to extract a particular type of ion beam from ion source 202.

The ion implanter 200 may further include one or more measurement components, arranged at one or more locations along the beam-line, between ion source 202 and a wafer held by platen 224. For simplicity, these components are shown as sensors 220. Examples of sensors 220 include ion beam current measurement devices, ion beam angle measurement devices, ion beam energy measurement devices, and ion beam size measurement devices. In one example, the sensors 220 may be a current detector such as a scanning detector, a closed loop current detector, and so forth. In one embodiment, for example, the sensors 220 may include a traveling Faraday 222, which is a closed loop Faraday current detector (CLF), for monitoring beam current provided to a substrate. The sensors 220 may be disposed to intercept the perturbed ion beam 216 and may be configured to record beam current of the perturbed ion beam 216, either at a fixed configuration, or as a function of configuration. In some examples, the beam current of perturbed ion beam 216 may be measured for a region of interest (ROI), such as the region of a substrate.

The sensors 220 measure the beam quality when a wafer is not being treated and communicates that to a controller, such as a control system 226. The controller then adjusts the physical configuration of one or more of the independently controlled tuning segments to help improve beam uniformity and angles. The sensors may include, for example, a “profiler” or traveling Faraday 222. The traveling Faraday 222 may be positioned behind a slit in a box that travels on the end of an articulated arm (not shown). The traveling Faraday 222 travels on the same plane where the platen 224 will later present the wafer for ion implant treatment. Behind the wafer plane are additional Faraday cups (not shown) that are referred to as “angle cups” since they are used to measure the angle of ion beamlets in the perturbed ion beam 216 at different locations.

The ion implanter 200 may also include a control system 226, which may be included as part of ion implanter 200, to control operations such as adjustments to ion beam parameters. These parameters may include ion beam energy, ion beam size, ion beam current, ion beam angle, and so forth. In turn, the control system 226 may adjust and control these parameters by adjusting the operation of various components of the aforementioned beamline components of the ion implanter 200. The control system 226 may be included in the ion implanter 200 or may be coupled to the ion implanter 200 in order to implement the AI and ML techniques for automatically tuning one or more components of the ion implanter 200 as set forth in the embodiments to follow. For example, the control system 226 may implement ML models, such as a control model to predict process parameters from control parameters, or an inverted control model to select control parameters which result in targeted process parameters. The control system 226 may include software to receive the predictions, and quickly configure one or more tuning segments of the tuning assembly 212 during a tuning cycle. This helps speed up throughput of the ion implanter 200, which is an amount of semiconductor wafers that can be processed over a given time period given by shortening tuneage times. It can also provide for some improved does and angle uniformity results, which is how even or consistent the beam current and incoming angles are at all configurations along a long dimension of the perturbed ion beam 216. This dimension is normally slightly longer than a diameter of a semiconductor wafer (e.g., 300 mm).

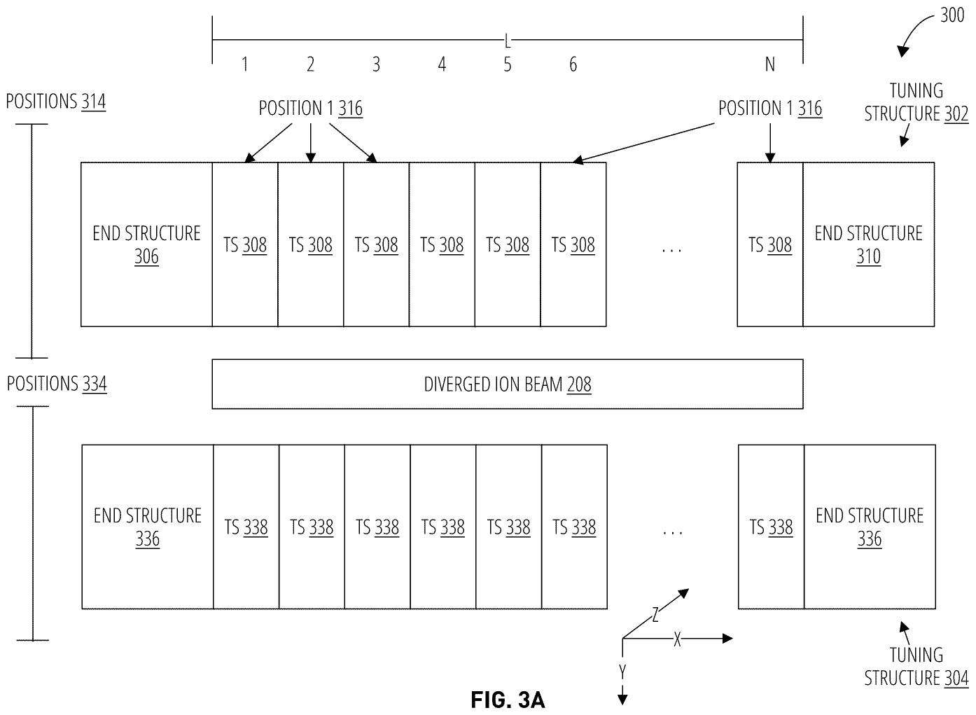

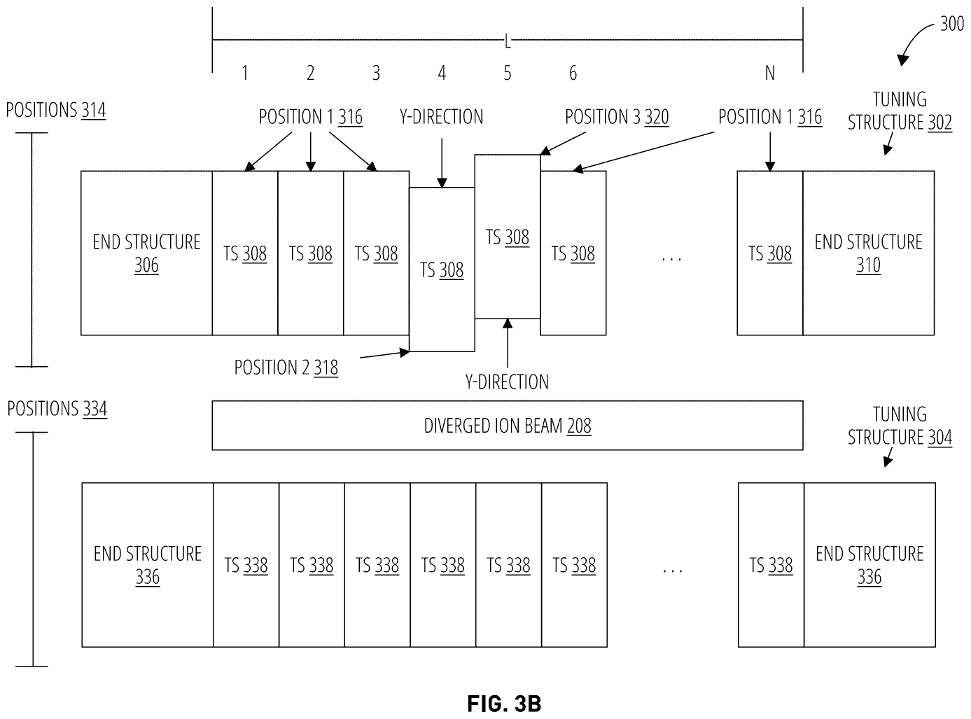

FIG. 3A illustrates an example of a configuration for a tuning assembly 212 implemented as an electrode assembly 300. Specifically, FIG. 3A is a side view in the Z direction of an electrode having an extraction slot with length L.

Depending on a given implementation, structures for the electrode assembly 300 (e.g., tuning segments) may be positioned above a path for the diverged ion beam 208, below the path for the diverged ion beam 208, or both above and below the path for the diverged ion beam 208. In one embodiment, for example, the tuning assembly 212 may comprise 18 rods (N=18) above the path of the diverged ion beam 208 and 18 rods (N=18) below the path of the diverged ion beam 208. Embodiments are not limited to this example.

FIG. 3A illustrates the electrode assembly 300 comprising a pair of tuning structures. A tuning structure 302 is positioned above the diverged ion beam 208 and a tuning structure 304 is positioned below the diverged ion beam 208. The tuning structure 302 comprises a set of tuning segments 308 (e.g., rods) above the diverged ion beam 208. The tuning structure 304 comprises a set of tuning segment 338 (e.g., rods) below the diverged ion beam 208. Each of the rods may move in the positive Y or negative Y direction. The rods do not typically move in the Z direction, which is the direction of travel of the diverged ion beam 208. The rods are positioned in various positions along the X direction.

As depicted in FIG. 3A, a ground electrode is individually partitioned into 1-N tuning segments 308, where N represents any positive integer. Each tuning segment 308 is distinctly partitioned from an adjacent tuning segment 308 such that one or more tuning segments 308 can be displaced in the Y direction, typically on the order of micrometers (μm). Similarly, a ground electrode is individually partitioned into 1-N tuning segments 338, where N represents any positive integer. Each tuning segment 338 is distinctly partitioned from an adjacent tuning segment 338 such that one or more tuning segments 338 can be displaced in the Y direction, typically on the order of μm.

The tuning segments 308 and the tuning segments 338 may move in a vertical direction to different positions 314 and positions 334, respectively, along a vertical axis in a Y direction. By way of example, tuning segments 308 number 1 through N are in a position 1 316, which is a default position that does not place any of the tuning segments 308 in the path of the diverged ion beam 208 leaving it unperturbed. The tuning segments 338 of the tuning structure 304 are in a similar position. The tuning segments 308 and/or tuning segments 338 may have any number of configurations based on a level of precision required by a tool, application, or recipe. Embodiments are not limited in this context.

FIG. 3B illustrates an example of a configuration for the tuning assembly 212 implemented as an electrode assembly 300 as depicted in FIG. 3A. Specifically, FIG. 3B is a side view in the Z direction of an electrode having an extraction slot with length L. It shows a set of tuning segments 308 (e.g., rods) above the diverged ion beam 208 and a set of tuning segment 338 (e.g., rods) below the diverged ion beam 208. These rods move in the positive Y and negative Y direction only, and typically not in the Z direction or the direction of travel of the diverged ion beam 208. The rods are positioned in various positions along the X direction.

FIG. 3B illustrates a case where some of the tuning segments 338 of the tuning structure 302 are configured to different positions 314 to perturb the diverged ion beam 208. The positions 334 of the tuning segments 338 of the tuning structure 304 remain in the default position for purposes of clarity. However, it may be appreciated that the positions 334 for the tuning segments 338 may also be configured to different positions to further perturb the diverged ion beam 208.

The tuning segments 308 may move in a vertical direction to different positions 314 along a vertical axis in a Y direction. For example, tuning segments 308 number 1, 2, 3, 6, and N are in a position 1 316, tuning segment 308 number 4 is in a position 2 318, tuning segment 308 is in a position 3 320, and so forth. The tuning segments 308 may have any number of configurations based on a level of precision required by a tool, application, or recipe. Embodiments are not limited in this context.

The tuning segment 308 number 4 and the tuning segment 308 number 5 are shown, for example, as being displaced in the Y direction perpendicular to the Z direction beam path, respectively. The partitioned tuning segments 308 are within the boundaries of a slot having length L. In particular, the tuning segment 308 number 1 is within the boundary of a first end structure 306 of the slot and the 308 number N is within the boundary of a second end structure 310 of the slot. Only tuning segments 308 within the slot area through which the diverged ion beam 208 passes are displaced. In this manner, local control of the beam current density in the beam profile is provided at a particular configuration along extraction slot length L by displacing one or more tuning segments 308 1-N. Each tuning segment 308 is distinctly partitioned from an adjacent tuning segment 308 such that each tuning segment 308 can be displaced in either the Y direction on the order of μm using, for example, one or more actuators (not shown) coupled to the tuning segments 308. Examples of actuators includes piezo actuators or micro-actuators.

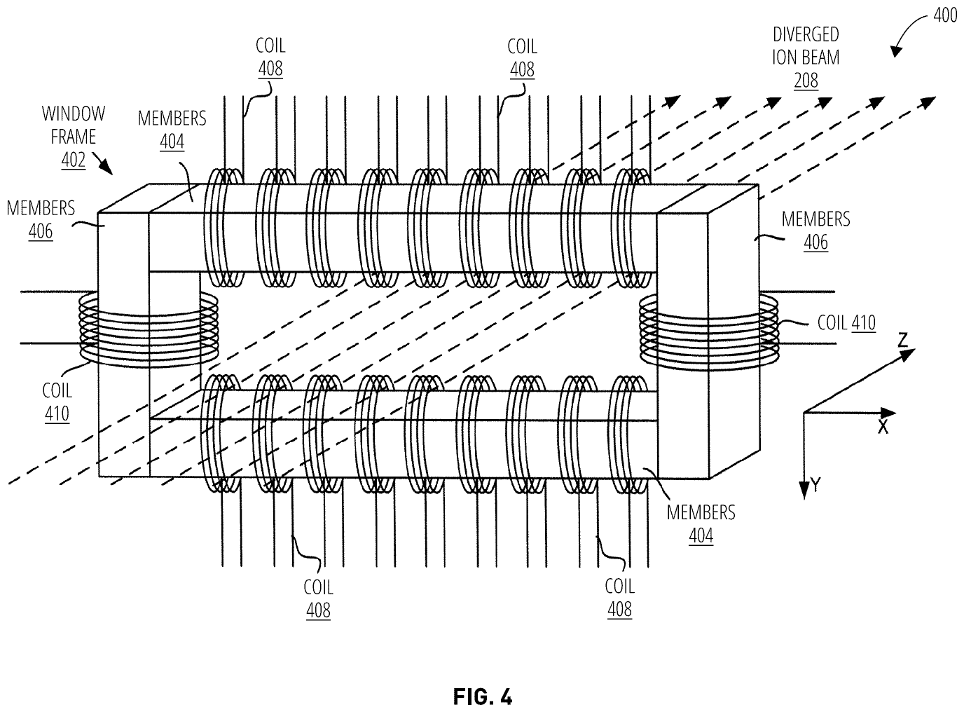

FIG. 4 illustrates an example of a configuration for the tuning assembly 212 implemented as a corrector-bar assembly 400 for providing active correction across the diverged ion beam 208. The active correction is achieved by passing the diverged ion beam 208 through the corrector-bar assembly 400.

The corrector-bar assembly 400 comprises a rectangular steel window frame 402 with an aperture to allow diverged ion beam 208 to pass through. The window frame 402 may comprise horizontal magnetic core members 404 and vertical magnetic core members 406. The window frame 402 provides a magnetic supporting structure needed for producing desired deflection fields. A plurality of coils 408 may be wound along the horizontal magnetic core members 404. Each coil 408 may be individually and/or independently excited with a current, so as to generate high-order multipole components without dedicated windings. Individual excitation of each coil 408, or each multipole, may deflect one or more beamlets within the diverged ion beam 208. That is, local variations in ion density or shape of the diverged ion beam 208 may be corrected by modifying the magnetic fields locally. These corrections may be made under computer control and on a time scale that is only limited by a decay rate of eddy currents in the horizontal magnetic core members 404.

Additional coils 410 may be wound around the vertical magnetic core members 406 to eliminate magnetic short circuits when multipole components are being generated. The coils 410 may also be excited independently to produce a pure dipole field in the Y direction between the horizontal magnetic core members 404. When the coils 410 are switched off, dipole fields may be generated in the X direction along the horizontal magnetic core members 404. These X- or Y-direction dipole fields may also be used to manipulate the diverged ion beam 208 or beamlet(s) therein.

As an alternative to the corrector-bar assembly 400 shown in FIG. 4, the corrector-bar assembly 400 may remove the vertical magnetic core members 406 or the coils 410. Apart from this difference, the corrector-bar assembly 400 may operate under substantially the same principles as previously described.

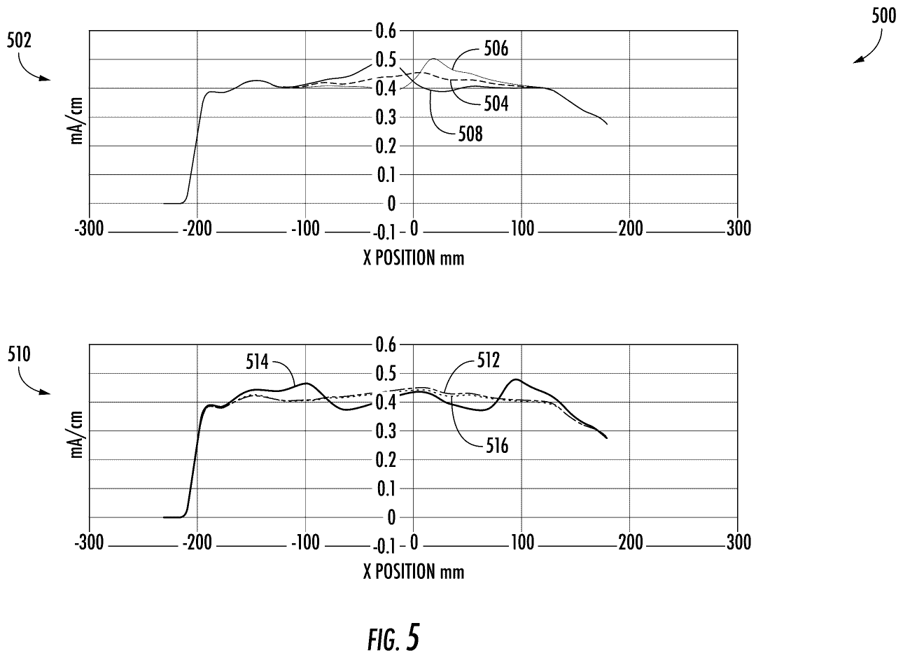

FIG. 5 illustrates a set of tuning profiles, such as displacement profiles 500. A tuning profile is a current density profile that shows a difference between a perturbed profile and an unperturbed profile. For example, a displacement profile is a current density profile that shows a difference between a perturbed profile and an unperturbed profile for the electrode assembly 300. The current density profile shows an effect of one or more tuning segments being modified, configured, or displaced. It captures the effects of perturbing one or more tuning segments 214. The displacement profiles 500 are examples of different current density profiles for an ion ribbon beam 204, such as the diverged ion beam 208. Specifically, the current density profiles illustrate plots of beam positions across a length of an elongated slot of an extraction electrode against beam current densities.

Graph 502 shows beam current (y-axis) versus configuration (x-axis) when a single tuning segment 308 of an electrode assembly 300 is adjusted or displaced, usually on the order of μm. As depicted in the graph 502, a dotted line 504 represents a base profile for a set of rods 1-N, where N is any positive integer, all at configuration 12.5. A line 506 represents tuning segment number 9 at configuration 18.5. The line 506 illustrates a plurality of variations in beam current densities relative to the line 504 when tuning segment number 9 is displaced, thereby causing non-uniformities above and below the line 504. It is noted that a dip occurs to the left side of a zero (0) configuration in mm (e.g., X=0) and a rise occurs to the right side of the 0 configuration relative to the line 504. Conversely, a line 508 represents tuning segment number 9 at 6.5 which causes a rise to the left side of the 0 configuration and a dip to the right side of the 0 configuration relative to the line 504.

Graph 510 shows beam current (y-axis) versus configuration (x-axis) when multiple tuning segments 308 of the electrode assembly 300 are adjusted or displaced. As depicted in the graph 510, a dotted line 512 represents a base profile for a set of rods 1-N, where N is any positive integer, all at configuration 12.5. A line 514 represents a tuning segment number 12 at configuration 6.5. The line 514 illustrates a plurality of variations in beam current densities relative to the line 514 when tuning segment number 12 is displaced, thereby causing non-uniformities relative to the line 514. It is noted that a dip occurs to the left side of a zero (0) configuration in mm (e.g., X=0), and the line 514 approximately aligns with the line 512 at the right side of the 0 configuration, relative to the line 514. Conversely, a line 516 represents tuning segment number 6 at a configuration 18.5, which causes approximate alignment between the line 516 and the line 514 to the left side of the 0 configuration, and a dip to the right side of the 0 configuration, relative to the line 514.

Since a typical wafer is 300 mm the configurations between-150 mm and +150 mm are of particular interest. As illustrated in graph 502 and graph 510, at the “rods base” condition the beam has varying current levels between-150 mm and +150 mm and after the rods are tuned the curve looks much better as the current level is relatively steady between-150 mm and +150 mm. It may be appreciated that the control system 226 may make fine adjustments for configurations of one or more tuning segments 308 of the electrode assembly 300, in response to measurements made by the sensors 220, thereby quickly adjusting the displacement profile for the diverged ion beam 208 to achieve a more uniform current density suitable for a given tool, application or recipe.

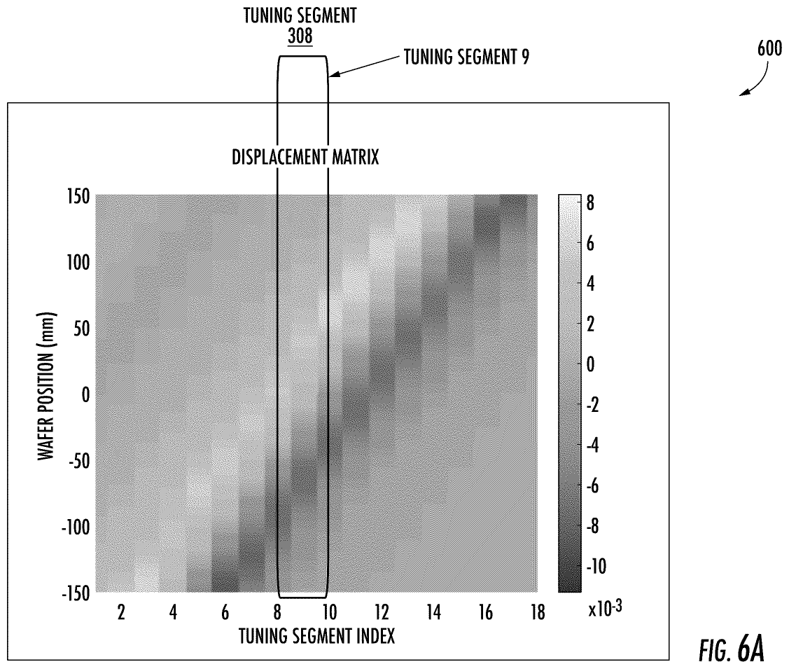

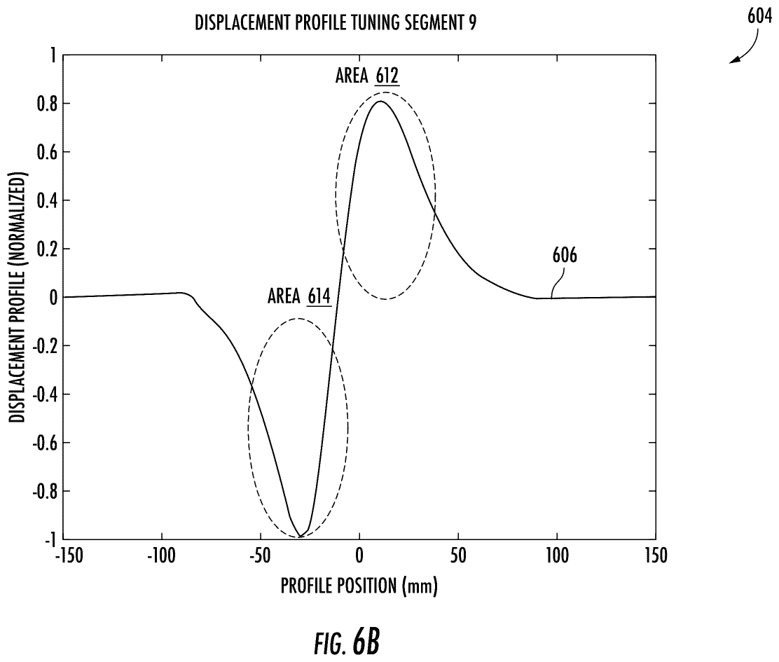

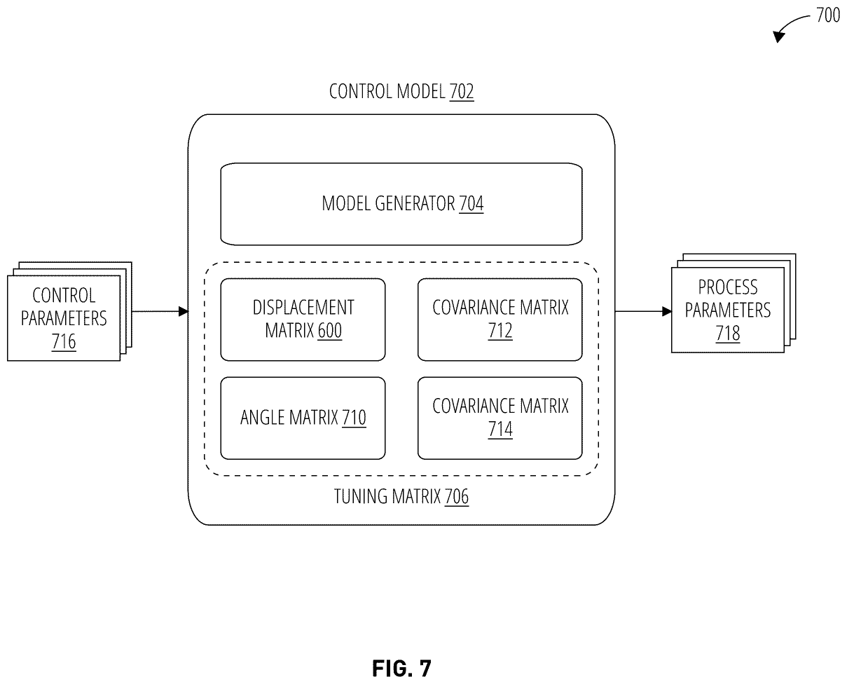

FIG. 6A illustrates a tuning matrix for the ion implanter 200. A tuning matrix stores parameters or values that represent an effect of changing one or more properties of a tuning segment 214 of the tuning assembly 212. One example of a tuning matrix is a displacement matrix 600 for the ion implanter 200. Specifically, the displacement matrix 600 illustrates current densities for various configurations of the tuning segments 308 of the electrode assembly 300. Another example of a tuning matrix is angle matrix for the ion implanter 200 as described with reference to FIG. 7. Yet another example of a tuning matrix is a coil matrix for or a coil angle matrix to represent current levels or angles, respectively, for the corrector-bar assembly 400. Embodiments are not limited to these examples.

In the context of ion implantation, a displacement matrix 600 is a matrix that represents the effect of changing electrode positions on ion current density during the ion implantation process. The displacement matrix 600 provides a visual representation of how the current density across the surface of the target material is changed when each electrode is adjusted. By analyzing the displacement matrix 600 illustrating the effects of adjusting electrode positions, researchers and engineers can gain insights into how the uniformity of ion implantation changes across the target material as electrode are adjusted, as well as gaining insight into the beam itself, helping to optimize the ion implantation process for desired material properties and characteristics. The displacement matrix 600 is a valuable tool for enhancing the precision and efficiency of ion implantation processes in various applications.

As depicted in FIG. 5A, the displacement matrix 600 illustrates the effect of adjusting various positions of the tuning segments 308 of the electrode assembly 300 on the resulting current densities. Each tuning segment 308 has a unique (learned) displacement profile which represents a dose change across a wafer when adjusting one or more tuning segments 308. A displacement profile for each tuning segment 308 is stored in the displacement matrix 600. The displacement matrix 600 is an example of combining multiple displacement profiles (e.g., similar to displacement profiles 500) for multiple tuning segments 308 of the electrode assembly 300. For example, assume the electrode assembly 300 has 18 tuning segments 308 (N=18). Each column represents a displacement profile associated with a tuning segment 1 through 18. For example, the highlighted column contains values for different profile configurations from −150 mm to +150 mm of the tuning segment 308 number 9 (e.g., tuning segment 9).

FIG. 6B illustrates a displacement profile 604 for the tuning segment 308 number 9 stored by the displacement matrix 600. As indicated in the displacement profile 604, when the tuning segment 308 number 9 is displaced relative to other tuning segments 308, such as adjacent tuning segments 308 number 8 and 10, the adjustment causes a plurality of variations in beam current densities within a normalized range of approximately 0.8 to −1 in area 612 and area 614, respectively, for configurations approximately-90 mm to +75 mm. It may be appreciated that similar displacement profiles for rods 1-8 and 10-18 may be derived from the displacement matrix 600 in a similar manner.

FIG. 7 illustrates an ML system 700. The ML system 700 is an example of an ML system suitable for implementation by a control system 226 for controlling a tuning assembly 212. As depicted in ML system 700, a control model 702 may comprise or instantiate a Bayesian linear regression model to predict horizontal angles and dose profiles based on configurations of one or more tuning segments 308 of the tuning assembly 212.

In one embodiment, for example, the control model 702 is arranged as a forward model to receive as input a set of control parameters 716 for the tuning assembly 212 of the ion implanter 200 and predict a set of process parameters 718 for the ion ribbon beam 204. For example, the set of control parameters 716 may represent configurations of one or more of the tuning segments 308 and/or tuning segments 338 (e.g., usually in μm) disrupting portions of the diverged ion beam 208, and the set of process parameters 718 may represent a current density and/or an implant angle for the diverged ion beam 208 to deliver ions to a wafer held by the platen 224 at an end station. The control model 702 is trained to predict horizontal angles and dose profiles based on tuning segment configurations. It is a linear (affine) model between tuning segment configurations and corresponding metrics. Each tuning segment has a unique (learned) displacement profile which represents dose changes across a wafer when adjusting one or more tuning segment 214. A tuning matrix 706 is generated and stored for the control model 702. The tuning matrix 706 may comprise, for example, a displacement profile for each tuning segment tuning segment is generated and stored in a displacement matrix 600. A similar matrix is generated and stored in an angle matrix 710 for the angle responses. In one embodiment, a covariance matrix 712 corresponding to the displacement matrix 600 and a covariance matrix 714 corresponding to the angle matrix 710 may be used to accelerate operations of the control model 702.

In various embodiments, the ML model is implemented as a Bayesian model using Bayesian statistics. Bayesian models are useful in machine learning because they provide a systematic framework for updating beliefs in the presence of uncertainty and can also give a measure of uncertainty in model predictions. In one embodiment, for example, the ML model is implemented as, or similar to, a Bayesian Linear Regression model. Other ML models may be used as well. Embodiments are not limited to this example.

In general, Bayesian linear regression is a statistical approach that combines the principles of Bayesian statistics with linear regression modeling. In traditional linear regression, the goal is to estimate the relationship between a dependent variable and one or more independent variables. Bayesian linear regression extends this by incorporating prior knowledge about the parameters of the regression model, allowing for a more robust and flexible analysis. In a Bayesian linear regression model, prior distributions are specified for the model coefficients, and these are updated using the observed data to obtain posterior distributions. This allows for the quantification of uncertainty in the estimates and provides a framework for incorporating prior knowledge into the analysis. Bayesian linear regression can be particularly useful when dealing with small or noisy datasets, as well as for handling complex models with many predictors. Potential advantages of Bayesian linear regression include the ability to make more informed and nuanced predictions, handle missing data, and integrate expert knowledge into the modeling process.

The control model 702 may use, at least in part, the displacement matrix 600 for predicting current densities and an angle matrix 710 for predicting implantation angles. In some embodiments, a model generator 704 may be implemented for generating or training the displacement matrix 600 and the angle matrix 710 for the control model 702. The model generator 704 may accelerate the training process for the displacement matrix 600 and the angle matrix 710 using a corresponding covariance matrix 712 and a covariance matrix 714, respectively.

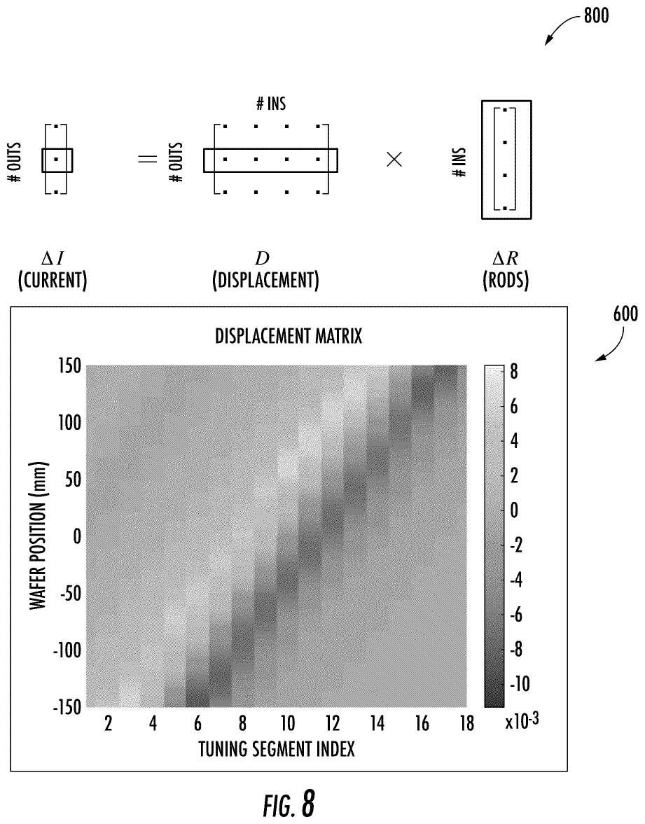

FIG. 8 illustrates an example of a more detailed view of an inferencing process for the model generator 704 using a displacement matrix 600 for the control model 702. It may be appreciated that similar techniques may be used for an angle matrix 710 of the control model 702.

In one embodiment, the control model 702 is implemented as a forward model where an implantation profile (I) is an affine (linear) function of a displacement matrix (D) and tuning segment configurations (R) as expressed in Equation (1):

$$I = {I}_{0} + D ( R - {R}_{0} ) \qquad EQUATION ( 1 )$$

Equation (1) simplifies to Equation (2):

$$Δ I = D ( Δ R ) \qquad EQUATION ( 2 )$$

Under this model, learning the displacement matrix 600 is the same or similar to learning how the dose and angle profiles change when adjusting rods. The displacement matrix 600 is initialized with approximate form and updated as new observations are collected. Each tuning segment 308 has a unique displacement function, and is not required to have a specific form (derivative of gaussian). This is significantly different from conventional current tuning algorithms. Embodiments implement a concurrent, analogous model for the angle matrix 710 for implant angles.

Learning the displacement matrix 600 is normally a difficult and time-consuming process. To fully learn the displacement matrix 600, at least one or more observations are needed for each tuning segment 308. Conventional techniques attempt to manually adjust each of the tuning segments 308 and measure resulting changes in current densities. However, this is a lengthy training process that takes the ion implanter 200 offline for longer periods of time, thereby rendering it idle as it learns a new displacement matrix 600 for different tools, beamline systems, recipes, preventative maintenance (PM) cycles, customer requirements, and so forth.

In some embodiments, training the displacement matrix 600 and the angle matrix 710 may be accelerated using a corresponding covariance matrix 712 and a covariance matrix 714, respectively. In the context of Bayesian linear regression, a covariance matrix generally represents the relationships between the variables in the model. Specifically, it quantifies the pairwise correlations between the different variables included in the regression model, as well as the uncertainties of the regression variables. In a Bayesian framework, the covariance matrix can be used to express the relationships between the latent variables involved in the model and can help in capturing complex dependencies between the input variables. This information can be valuable for understanding the structure and patterns within the data, as well as for making predictions based on the Bayesian linear regression model.

In one embodiment, for example, the covariance matrix 712 and the covariance matrix 714 may comprise experimentally measured values. In one embodiment, for example, the covariance matrix 712 and the covariance matrix 714 may comprise synthetic values derived from measured values. Embodiments are not limited in this context.

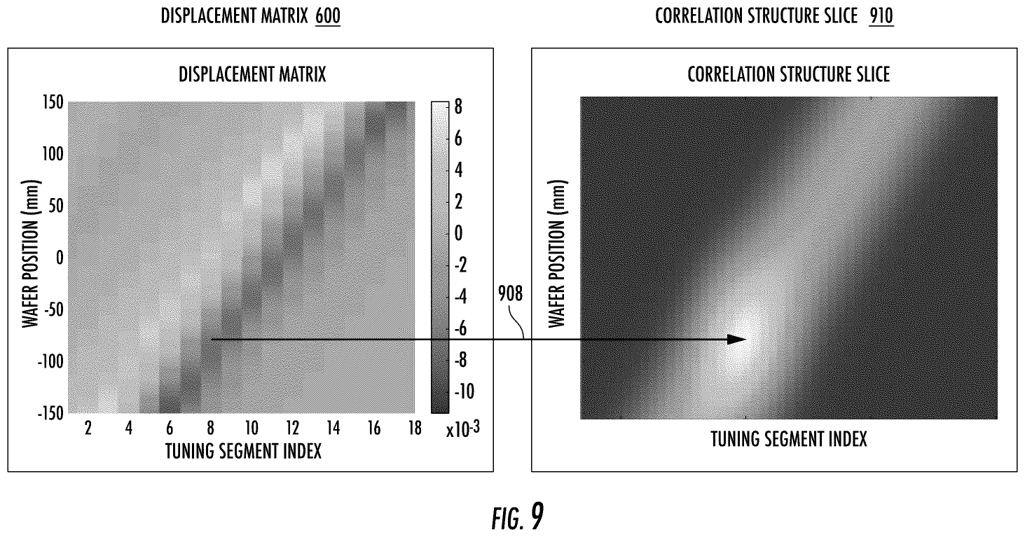

FIG. 9 illustrates a more detailed example of the displacement matrix 600 and a correlation structure slice 910. The correlation structure slice 910 may be stored separate from, or as part of, the covariance matrix 712. The model generator 704 is arranged to manage, create, revise, update, or delete (CRUD operations) one or more of the matrices used by the control model 702, such as the displacement matrix 600, angle matrix 710, covariance matrix 712, and/or covariance matrix 714.

As depicted in FIG. 9, the displacement matrix 600 and the correlation structure slice 910, which represents one segment of a larger correlation matrix, may comprise matrices having the same or similar dimensions. The correlation structure slice 910 shows how the marked point in the displacement matrix 600 relates to each other point in the displacement matrix 600. So, if there are N points in the displacement matrix, there are N² points in the full correlation matrix and/or the covariance matrix 712, e.g., one point for each pair of points in the displacement matrix 600.

Each cell of the displacement matrix 600 corresponds to a row or column in the covariance matrix 712. Line 908 indicates the shared location of both the marked point in the displacement matrix, and its corresponding center in the correlation structure slice 910, which shows the correlation of the point marked in displacement matrix 600 to all other model parameters shown in the displacement matrix 600. As the model generator 704 initializes and builds the displacement matrix 600 with values representing new observations for the tuning segments 308 1-N, the model generator 704 determines the most likely displacement matrix 600 given a prior belief of how elements in displacement matrix 600 are related, as described by the covariance matrix 712. The correlation structure slice 910 may comprise measured values or synthetic values from measured values. It is typically pre-generated prior to building the displacement matrix 600. Thus, as the displacement matrix 600 receives new observations it adds this information to its current belief by finding the most likely new displacement matrix given the prior belief, new observation, and the covariance matrix 712. This process continues for some number of observations (e.g., 5 to 7 observations) until the displacement matrix 600 is complete.

In one embodiment, for example, the model generator 704 is arranged to initialize, create or update a displacement matrix 600, D, starting with a representation of a belief as a high-dimensional normal random variable. Each parameter of D is a dimension in this multivariate random variable, as expressed in Equation (3):

$$D ∼ N ( {μ}_{D} , {\sum }_{D} ) \qquad Equation ( 3 )$$

In Equation (3), up represents a mean belief and 2D represents a covariance matrix, such as the covariance matrix 712 and/or covariance matrix 714. The model generator 704 initializes the control model 702 with an approximate prior belief in order to prevent overfitting. Under this framework, the model generator 704 updates the control model 702 using a Bayesian update with new observations. The resulting distribution is also normal, as expressed in Equation (4):

$$P ( D \vert R , I ) ∝ P ( I \vert R , D ) * P ( D ) \qquad Equation ( 4 )$$

This normal distribution allows for continuous updates each in a defined amount of time.

The control model 702 is updated using each new observation with a Bayesian belief update which is conceptually the probability of a new observation (control parameters, R, and resulting current or angle profile, I) given the probability of the prior belief, as expressed in Equation (5):

$$P ( D \vert R ) ∝ P ( I \vert R , D ) * P ( D ) \qquad Equation ( 5 )$$

The posterior can be rewritten as a new multivariate Gaussian in closed form, which incorporates new tuning segment configurations (R), new dose profile (I), observation noise (Σ_{N}), and prior belief (μ_{D}, Σ_{D}), as expressed in Equation (6), Equation (7), and Equation (8):

$$N ( {μ}_{{D}^{*}} , {\sum }_{{D}^{*}} ) \qquad Equation ( 6 )$$

$${μ}_{{D}^{*}} = \frac{{R}_{kron}^{T} * {\sum }_{n}^{- 1} * {R}_{kron} * I + {\sum }_{D}^{- 1} * {μ}_{D}}{{R}_{kron}^{T} * {\sum }_{N}^{- 1} * {R}_{kron} + {\sum }_{D}^{- 1}} \qquad Equation ( 7 )$$

$${\sum }_{{D}^{*}}^{- 1} = {R}_{kron}^{T} * {\sum }_{N}^{- 1} * {R}_{kron} + {\sum }_{D}^{- 1} \qquad Equation ( 8 )$$

Where Rₖᵣₒₙ is the Kronecker product of the rod positions and the newly observed implants stored along the diagonal of an otherwise blank, square, matrix, as expressed in Equation (9):

$${R}_{kron} = R ⊗ diag ( I ) \qquad Equation ( 9 )$$

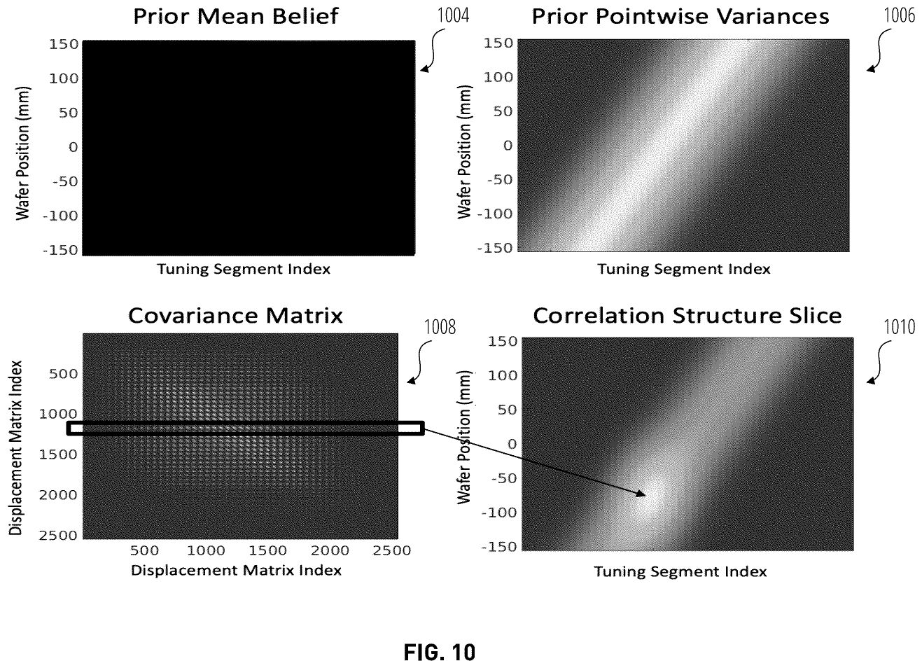

A technique to create the prior belief (μ_{D}, Σ_{D}) is described with reference to FIG. 10.

FIG. 10 illustrates a series of matrices demonstrating prior belief creation. As previously discussed, training the displacement matrix 600 or the angle matrix 710 is a tedious and time-consuming process. Using a generic prior belief will result in a slow convergence. The model generator 704 accelerates training through use of one or more pre-trained covariance matrices, such as the covariance matrix 712 and the covariance matrix 714.

Having a realistic and physics informed prior belief is instrumental to rapid tuning. The prior belief (μ_{D}, Σ_{D}) includes a mean model belief (μ_{D}) that begins as a blank matrix 1004. An important part of the prior belief is the covariance matrix (Σ_{D}). Elements of the covariance matrix 1008 Σ_{D,I.j} have two components. The first component is pointwise variances (σ_{i/j}) as depicted in matrix 1006. The second component is correlation coefficients (p), one slice of which are depicted in matrix 1010. This is expressed in Equation (10):

$${\sum }_{D , i , j} = {σ}_{i} * {σ}_{j} * {ρ}_{i , j} \qquad Equation ( 10 )$$

The covariance matrix 1008 Σ can be empirically learned or parameterized using knowledge from physics, experienced personnel, or other sources. Pointwise variances (σ_{i/j}) are the uncertainties of individual model coefficients. Correlation coefficients (p) describe how elements of D are related to one another. They may consider local correlation, trans-wafer correlation, additional pointwise uncertainty, as well as other prior beliefs. One slice of the full correlation coefficient structure, reshaped to have the same shape as the displacement matrix 600, is depicted in the correlation structure slice 910, which shows the starting correlation belief of one coefficient in the displacement matrix 600, to all others displacement matrix coefficients.

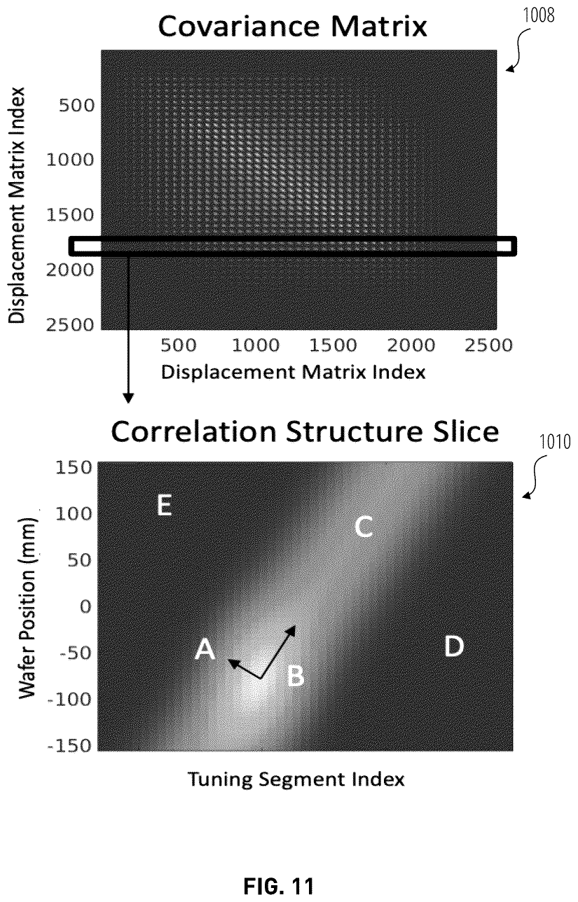

FIG. 11 illustrates one embodiment of a prior belief parameterization, as first shown in the correlation structure slice of the correlation structure slice 910. For prior belief and hyperparameters, there are different ways to define the prior covariance matrix. In one embodiment, for example, the model generator 704 uses a parameterized physics information prior belief. The matrix 1008 and the matrix 1010 illustrates some parameters that define the prior belief including: (1) A/B for length scales for wafer/beam configuration correlation; (2) C for “trans-wafer” correlation coefficients; (3) D for minimum model (correlated) uncertainty; (4) E for pointwise (uncorrelated) uncertainty; (5) F for observation noise (not shown); and (6) G for width/height of pointwise variances (not shown). Other hyperparameters include termination criteria parameters, regularization coefficients, and weighting of horizontal angle and dose optimization bias. Examples of termination criteria may include: (1) when model predictions are (a) very close to observation, (b) very close to model globally predicted optima, and (c) within specification; (2) when uniformity specifications are exceeded; (3) when no recent improvements are made; (4) hitting a maximum number of iterations; or (5) receiving an abort signal from a higher level control system

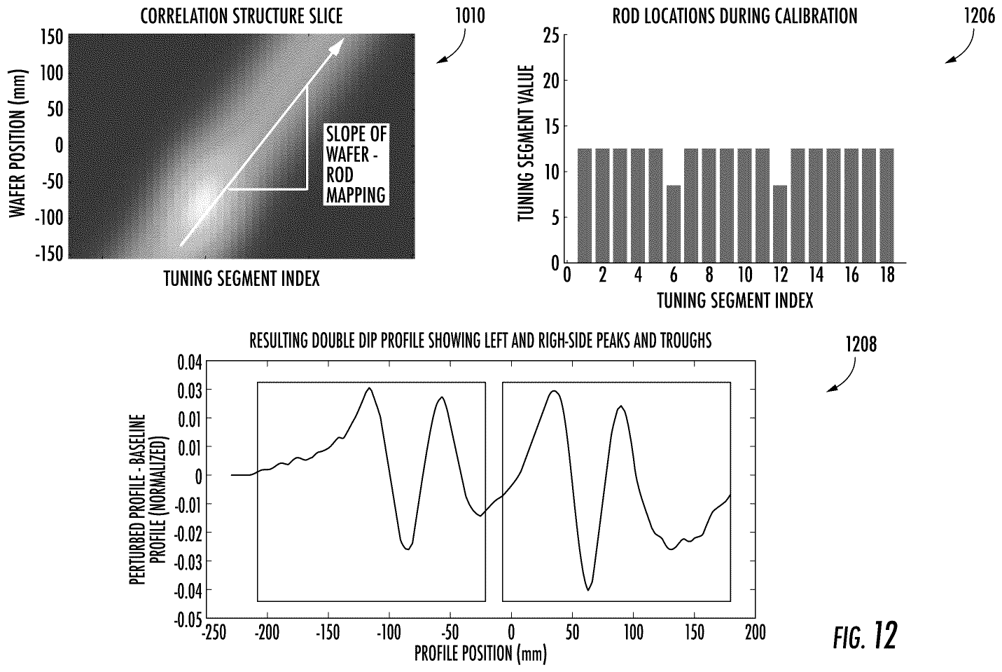

FIG. 12 illustrates a process for calibrating the control model 702. As depicted by the correlation structure slice 910, determining an approximate area of effect for each tuning segment can often improve model convergence. As tool conditions change from setup to setup, each tuning segment will affect slightly different location of the wafer on each setup. This mapping of a tuning segment number to approximate area of effect on wafer is recalculated on each setup, which provides better model prior beliefs, thus reducing the number of required tuning iterations. This can be done by perturbing a small number of tuning segments, either individually, or simultaneously, and determining their center of effect before extrapolating these locations to other tuning segments. Here, the model generator 704 initializes the control model 702 by determining the approximate areas affected by perturbing certain tuning segments (e.g., rods 6 and 12), then these locations are extrapolated to all other rods by calculating the slope of the wafer-rod mappings. The troughs and peaks of the left and right dip, as depicted in graph 1206 and graph 1208 can then be identified and these locations then are used to calculate the central impact location for the two perturbed rod. This gives approximate wafer impact locations for each perturbed rod, which can then be extrapolated to all rods. After initializing the model, this double dip is also learned using the standard belief update, and allows the model generator 704 to initialize an approximation of the underlying system as captured in the displacement matrix 600.

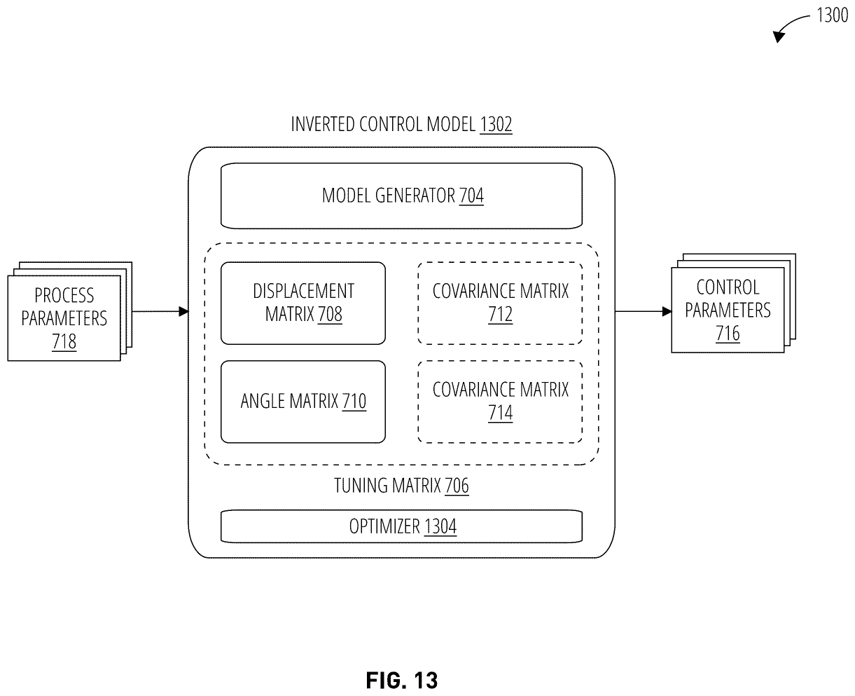

FIG. 13 illustrates an ML system 1300. The ML system 1300 is another example of an ML system suitable for implementation by a control system 226 for controlling a tuning assembly 212. As depicted in ML system 1300, an inverted control model 1302 may comprise or instantiate a Bayesian linear regression model to select configurations of one or more tuning segment 214 of the tuning assembly 212 based on target horizontal angles and dose profiles and the displacement matrix 600 and angle matrix 710, respectively.

In one embodiment, for example, the inverted control model 1302 is arranged as a forward model to receive as input a set of process parameters 718 for ion ribbon beam 204 and select, configure, predict, suggest or infer a set of control parameters 716 for the tuning assembly 212 of the ion implanter 102. For example, the set of process parameters 718 may comprise a current density and/or an implant angle for the diverged ion beam 208, and the set of control parameters 716 may comprise configurations of one or more of the tuning segment 214 disrupting portions of the ion ribbon beam 204. A tuning matrix 706 is generated and stored for the inverted control model 1302. In one embodiment, for example, the tuning matrix 706 comprises the displacement matrix 600 and/or angle matrix 710, which are populated with a suitable number of observations or samples (e.g., trained), the inverted control model 722 may use the displacement matrix 600 and the angle matrix 710 to select control parameters 716 from process parameters 718.

Once the model generator 704 creates and updates the displacement matrix 600 and the angle matrix 710, the matrices may be used by the inverted control model 1302. More formally, new positions for one or more tuning segment 214 are optimized given a dose model (DI), an angle model (DA), or a combination thereof. During optimization, an optimizer 1304 minimizes the predicted cost using an optimization method such as gradient descent or some other appropriate optimization method. An example of a formula for predicted cost is expressed in Equation (11) which balances the cost of imperfect angles, imperfect dose, and a regularization term which prevents overfitting:

$$Cost = predicted angle non - uniformity + predicted dose non - uniformity + regularization \qquad Equation ( 11 )$$

More formally, Equation (11) may be expressed as Equation (12) using the difference between the predicted angles A_{pred} and the desired angled A_{desired}, the difference between the predicted current profile I_{pred} and the desired current profile I_{desired}, and the difference between the previous rod locations R_{base} and new rod locations R:

$$cost = ( 1 - α ) {( \frac{{A}_{pred} - {A}_{desired}}{{C}_{A}} )}^{2} + ( α ) {( \frac{{I}_{pred} - {I}_{desired}}{{C}_{I}} )}^{2} + λ \sum ( {R}_{i} - {R}_{i , base} ) \qquad Equation ( 12 )$$

In Equation (12), C_{A} and Cₗ are coefficients used to normalize the costs of imperfect angles and current densities, while 0<α<1 determines weighting of angles versus dose. Finally, λ determines how aggressive to tune by incurring a penalty based on how much the electrodes change from iteration to iteration, which is a regularization technique added to prevent overcompensation and/or overfitting.

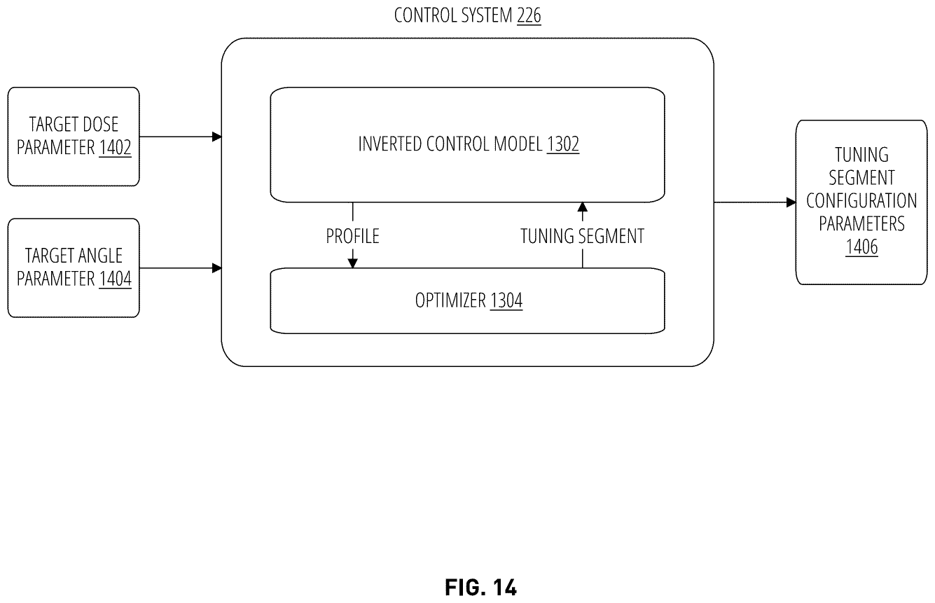

FIG. 14 illustrates an example of the control system 226 implementing the inverted control model 1302 and the optimizer 1304 in an iterative manner. As depicted in FIG. 14, the control system 226 receives a set of process parameters 718, such as a target dose parameter 1402 and a target angle parameter 1404. The inverted control model 1302 receives as input the target dose parameter 1402 and the target angle parameter 1404, and begins an iterative process to find and select one or more control parameters 716 for the tuning segment 214 of the tuning assembly 212 that causes the ion implanter 200 to generate an ion ribbon beam 204 that delivers ions to a substrate that matches the target dose parameter 1402 and the target angle parameter 1404. The inverted control model 1302 passes one or more displacement profiles from displacement matrix 600 to the optimizer 1304. The optimizer 1304 optimizes a configuration for a tuning segment 214 and passes the configuration to the 1302. This process repeats until the inverted control model 1302 determines a target configuration for the tuning segment 214 of the tuning assembly 212. Once the target configuration is found, the inverted control model 1302 outputs control parameters 716, such as one or more tuning segment configuration parameters 1406. The tuning segment configuration parameters 1406 are passed to the control system 226, which configures the tuning segment 214 of the tuning assembly 212 using the tuning segment configuration parameters 1406. The ion implanter 200 may then operate to generate the ion ribbon beam 204.

Operations for the disclosed embodiments may be further described with reference to the following figures. Some of the figures may include a logic flow. Although such figures presented herein may include a particular logic flow, it can be appreciated that the logic flow merely provides an example of how the general functionality as described herein can be implemented. Further, a given logic flow does not necessarily have to be executed in the order presented unless otherwise indicated. Moreover, not all acts illustrated in a logic flow may be required in some embodiments. In addition, the given logic flow may be implemented by a hardware element, a software element executed by a processor, or any combination thereof. The embodiments are not limited in this context.

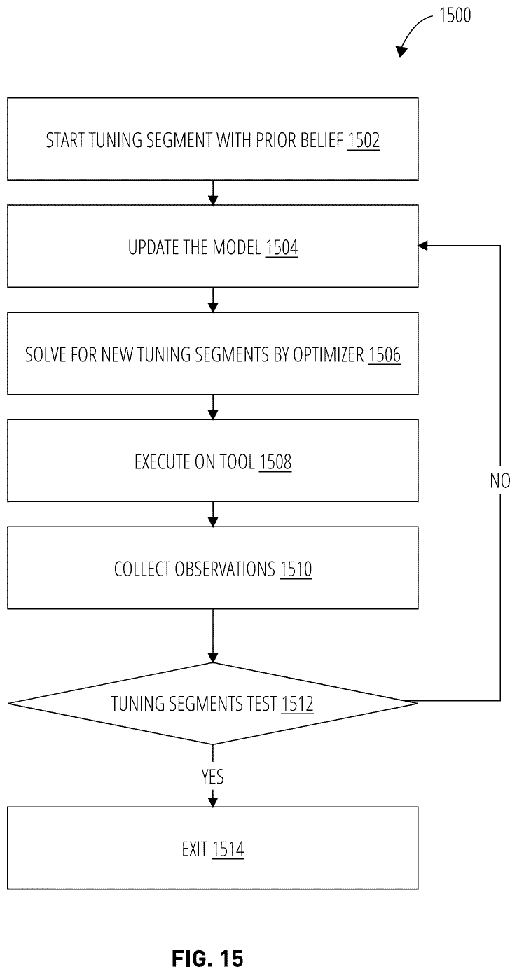

FIG. 15 illustrates an embodiment of a logic flow 1500. The logic flow 1500 may be representative of some or all of the operations executed by one or more embodiments described herein. For example, the logic flow 1500 may include some or all of the operations performed by devices or entities within the ML system 1300, such as the control system 226. More particularly, the logic flow 1500 illustrates an example where the ML system 1300 performs a set of inferencing operations for the control system 226 in an iterative manner.

As depicted in logic flow 1500, at block 1502 the prior model is initialized and begins configuration of a tuning segment, such as one or more tuning segment 214 of the tuning assembly 212. At block 1504, the inverted control model 1302 is updated. At block 1506, the optimizer 1304 solves for new tuning segment 214 of the tuning assembly 212. At block 1508, the model is executed on a given tool, such as ion implanter 200. At block 1510, one or more sensors 220 gather one or more observations on tool performance. At decision block 1512, the control system 226 determines whether the tuning segments pass testing. If the tuning segment 214 do not pass, control is passed back to block 1504. If the tuning segment 214 pass, the process exits at block 1514.

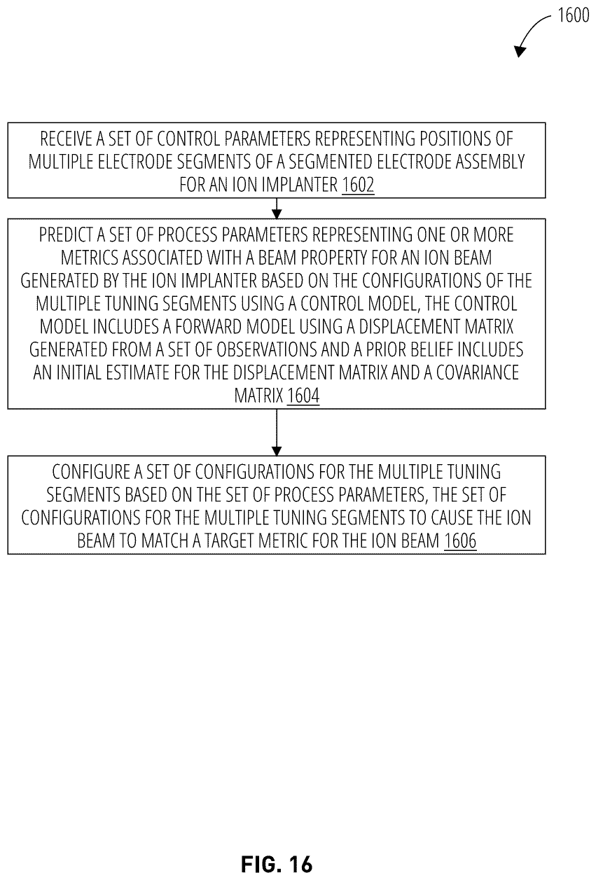

FIG. 16 illustrates an embodiment of a logic flow 1600. The logic flow 1600 may be representative of some or all of the operations executed by one or more embodiments described herein. For example, the logic flow 1600 may include some or all of the operations performed by devices or entities within the ML system 700, the ML system 1300, an inferencing system 1700, a device 1702, a training system 1800, or the training device 1816. More particularly, the logic flow 1600 illustrates an example where the ML system 700 or the ML system 1300 performs inferencing operations for one or more of ML models 1724.

In block 1602, logic flow 1600 receives a set of control parameters representing configurations of multiple tuning segments of a tuning assembly for an ion implanter. In block 1604, logic flow 1600 predicts a set of process parameters representing one or more metrics associated with a beam property for an ion beam generated by the ion implanter based on the configurations of the multiple tuning segments using a control model, the control model includes a forward model using a displacement matrix generated from a set of observations and a prior belief includes an initial estimate for the displacement matrix and a covariance matrix. In block 1606, logic flow 1600 configures a set of configurations for the multiple tuning segments based on the set of process parameters, the set of configurations for the multiple tuning segments to cause the ion beam to match a target metric for the ion beam.

By way of example, the control model 702 receives a set of control parameters 716 representing configurations of multiple tuning segment 214 of a tuning assembly 212 for an ion implanter 102. The control model 702 predicts a set of process parameters 718 representing one or more metrics associated with a beam property for an ion ribbon beam 204 generated by the ion implanter 102 based on the configurations of the multiple tuning segment 214. The control model 702 includes a forward model using a displacement matrix 600 generated from a set of observations and a prior belief comprises an initial estimate for the displacement matrix 600 and a covariance matrix 712. The control system 226 configures a set of tuning segment configuration parameters 1406 for the multiple tuning segment 214 based on the set of process parameters 718, the set of configurations for the multiple tuning segment 214 to cause the ion ribbon beam 204 to match a target metric for the ion ribbon beam 204.

In one embodiment, for example, the forward model is an affine function of the displacement matrix 600 and configurations of the multiple tuning segment 214.

In one embodiment, for example, the displacement matrix 600 includes a set of displacement profiles 500, where each displacement profile represents a change in current density values versus configurations on a wafer for a change in configuration of a tuning segment.

In one embodiment, for example, the forward model is a Bayesian linear regression model, The model generator 704 initializes the displacement matrix 600 with an approximate prior belief, which contains a mean belief of the displacement matrix 600, and a corresponding covariance matrix 712, where each parameter of the displacement matrix 600 includes a mean belief component and the covariance matrix 712 describes an uncertainty and a relationship between elements of the displacement matrix 600. The model generator 704 updates the displacement matrix 600 and the covariance matrix 712 with a new observation using a Bayesian belief update which includes a probability of observation and a probability of a prior belief.

In one embodiment, for example, the one or more metrics comprise a current density or an implant angle for the ion ribbon beam 204.

In one embodiment, for example, the model generator 704 generates the prior belief covariance matrix 712 using a parameterized physics informed prior belief defined by a set of parameters that includes length scales for wafer and beam configuration correlation, transwafer correlation coefficient, minimum model uncertainty, pointwise uncertainty, observation noise, or width and height of pointwise variances.

In one embodiment, for example, an ion implanter 200 includes an ion source 202 to generate an ion ribbon beam 204. The ion implanter 200 also includes a tuning assembly 212 that includes multiple tuning segment 214 to control the ion ribbon beam 204. The ion implanter 200 also includes a control system 226 coupled to the tuning assembly 212 to control a configuration for a tuning segment of the multiple tuning segment 214, the control system 226 includes circuitry to receive a set of control parameters 716 representing configurations of the multiple tuning segment 214 of the tuning assembly 212 for the ion implanter 200, predict a set of process parameters 718 representing one or more metrics associated with a beam property for an ion ribbon beam 204 generated by the ion implanter 200 based on the configurations of the multiple tuning segment 214 using a control model 702, the control model 702 to include a forward model using a displacement matrix 600 generated from a set of observations and a prior belief that includes an initial estimate for the displacement matrix 600 and a covariance matrix 712. The control system 226 may configure the multiple tuning segment 214 based on the set of process parameters 718 to cause the ion ribbon beam 204 to match a target metric for the ion ribbon beam 204.

In one embodiment, for example, the displacement matrix 600 includes a set of displacement profiles 500, where each displacement profile represents a change in current density values versus configurations on a wafer for a change in configuration of a tuning segment.

In one embodiment, for example, the forward model is a Bayesian linear regression model, the circuitry to initialize the tuning and covariance matrices with an approximate prior belief, where each parameter of the displacement matrix 600 represents a mean belief component and a covariance component represents a relationship and certainty of two displacement matrix components, and updating the displacement of covariance matrices with a new observation using a Bayesian belief update that includes a probability of observation and a probability of a prior belief.

In one embodiment, for example, the circuitry generates the covariance matrix 712 using a parameterized physics informed prior belief defined by a set of parameters includes length scales for wafer and beam configuration correlation, transwafer correlation coefficient, minimum model uncertainty, pointwise uncertainty, observation noise, or width and height of pointwise variances.

In one embodiment, for example, the one or more metrics comprise a current density or an implant angle for the ion ribbon beam 204.

In one embodiment, for example, the tuning assembly 212 includes an electrode assembly 300 and the tuning segment 214 comprise a set of rods with at least one rod with a different position relative to the other rods, or a corrector-bar assembly 400 includes a set of magnetic core members 404 and the tuning segment 214 comprise a set of coils 408 and/or coils 410 distributed along the set of magnetic core members 404 and/or members 406 with at least one coil with a different current level relative to the other coils.

In one embodiment, for example, the circuitry causes the ion implanter 200 to generate the ion ribbon beam 204 based on the configured multiple tuning segment 214 of the tuning assembly 212 to deliver ions to the silicon wafer.

In one embodiment, for example, an ion implanter 200 includes an ion source 202 to generate an ion ribbon beam 204. The ion implanter 200 also includes a tuning assembly 212 that includes multiple tuning segment 214 to control the ion ribbon beam 204. The ion implanter 200 also includes a control system 226 coupled to the tuning assembly 212 to control a configuration for a tuning segment of the multiple tuning segment 214, the control system 226 to include circuitry to receive a set of process parameters 718 representing one or more metrics associated with a beam property for the ion ribbon beam 204 generated by the ion implanter 200, select a set of control parameters 716 representing configurations of the multiple tuning segment 214 of the tuning assembly 212 for the ion implanter 200 based on the set of process parameters 718 using an inverted control model 722, the inverted control model 722 to include a forward model using a displacement matrix 600 generated from a set of observations and a prior belief. The control system 226 may configure the multiple tuning segment 214 based on the set of control parameters 716 to cause the ion ribbon beam 204 to match a target metric for the ion ribbon beam 204.

In one embodiment, for example, the displacement matrix 600 includes a set of displacement profiles 500, where each displacement profile represents a change in current density values versus configurations on a wafer for a change in configuration of a tuning segment.

In one embodiment, for example, the forward model is a Bayesian linear regression model, the circuitry to initialize the displacement matrix 600 with an approximate prior belief, where each parameter of the displacement matrix 600 represents a mean belief component and a covariance matrix 712 that represents a certainty of the approximate prior belief, and how elements of the displacement matrix 600 are believed to be related to one another, and update the approximate prior belief which includes a displacement matrix mean belief, and its covariance matrix 712, with a new observation using a Bayesian belief update includes a probability of observation and a probability of a prior belief.

In one embodiment, for example, the circuitry to generate the covariance matrix 712 using a parameterized physics informed prior belief defined by a set of parameters includes length scales for wafer and beam configuration correlation, transwafer correlation coefficient, minimum model uncertainty, pointwise uncertainty, observation noise, or width and height of pointwise variances.

In one embodiment, for example, the one or more metrics comprise a current density or an implant angle for the ion beam.

In one embodiment, for example, the tuning assembly 212 includes an electrode assembly 300 and the tuning segment 214 comprise a set of rods with at least one rod with a different position relative to the other rods, or a corrector-bar assembly 400 includes a set of magnetic core members 404 and/or members 406 and the tuning segments comprise a set of coils 408 and/or coils 410 distributed along the set of magnetic core members 404 and/or members 406 with at least one coil with a different current level relative to the other coils.

In one embodiment, for example, the circuitry causes the ion implanter 200 to generate the ion ribbon beam 204 based on the configured configurations of the multiple tuning segment 214 of the tuning assembly 212 to deliver ions to a silicon wafer.

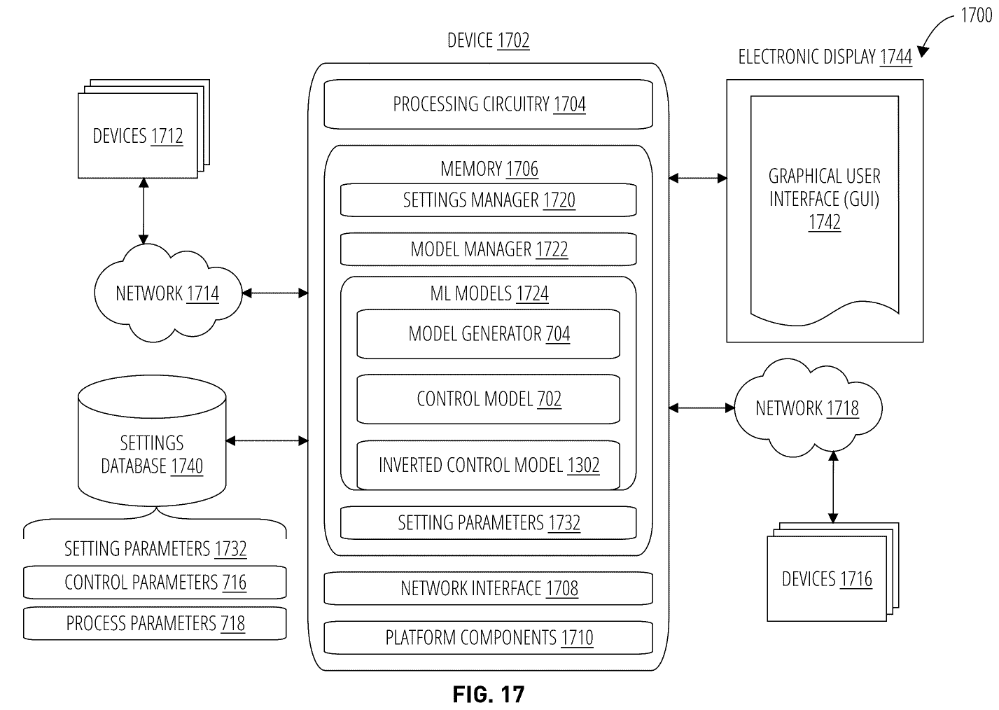

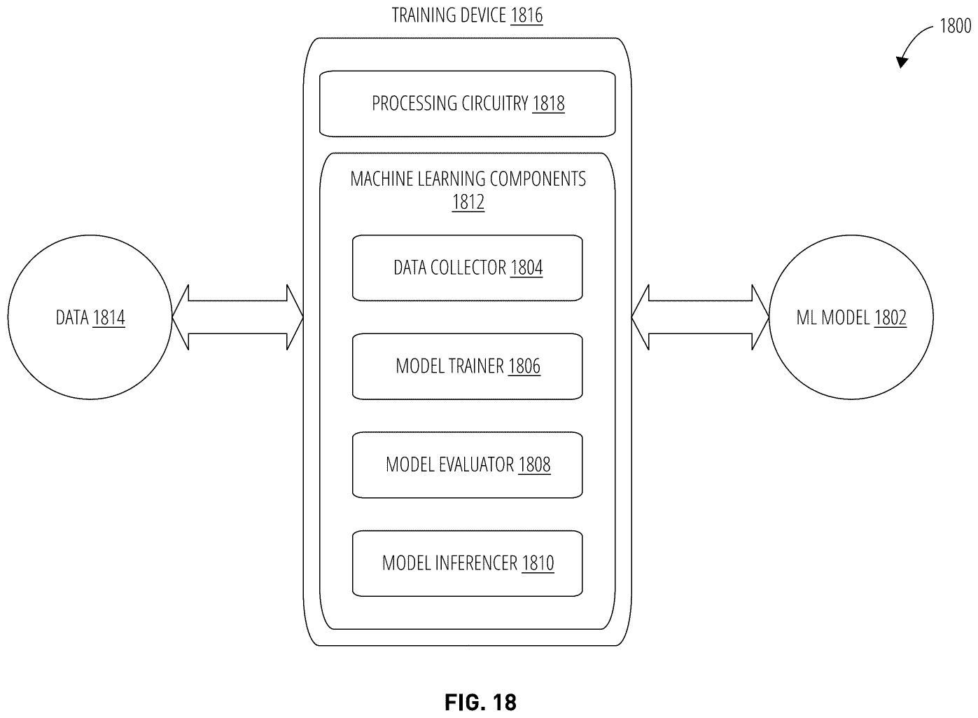

FIG. 17 illustrates an embodiment of an inferencing system 1700. The inferencing system 1700 may be suitable for implementing one or more embodiments as described herein. In one embodiment, for example, the inferencing system 1700 may implement a set of trained ML models 1724, including a control model 702 and an inverted control model 722. An example of a training system suitable for training the ML models 1724 is described with reference to FIG. 18.

As depicted in FIG. 17, the inferencing system 1700 may comprise a device 1702 communicatively coupled to a set of devices 1712 via a network 1714. The device 1702 may also be communicatively coupled to a set of devices 1716 via a network 1718. It may be appreciated that the inferencing system 1700 may have more or less devices than shown in FIG. 17 with a different network topology as needed for a given implementation. Embodiments are not limited in this context.

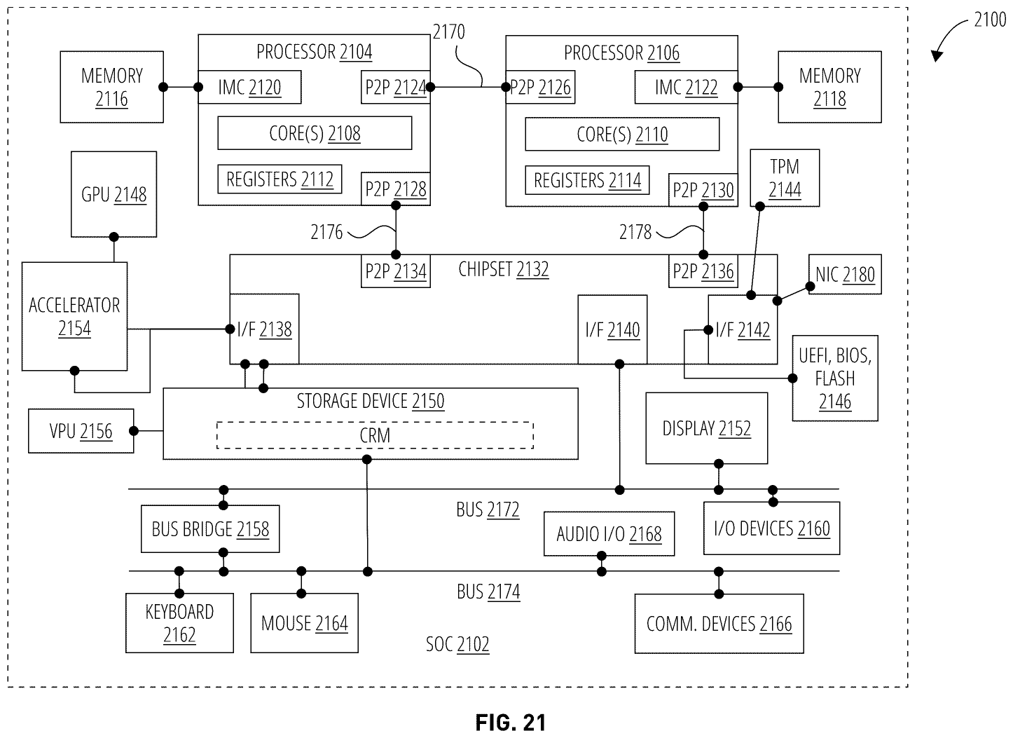

In various embodiments, the device 1702 may comprise various hardware elements, such as a processing circuitry 1704, a memory 1706, a network interface 1708, and a set of platform components 1710. Similarly, the devices 1712 and/or the devices 1716 may include similar hardware elements as those depicted for the device 1702. The device 1702, devices 1712, and devices 1716, and associated hardware elements, are described in more detail with reference to a computing architecture 2100 as depicted in FIG. 21.

In various embodiments, the devices 1702, 1712 and/or 1716 may communicate control, data and/or content information associated with the ion implanter 102 via one or both network 1714, network 1718. The network 1714 and the network 1718, and associated hardware elements, may be implemented in accordance with a given wireless or wired communications architecture, such as a gigabit ethernet wired network, an IEEE 802.11 (“WiFi”) wireless network, or a 3GPP 5G or 6G wireless network, among other types of networks.

The memory 1706 may comprise a set of computer executable instructions that when executed by the processing circuitry 1704, causes the processing circuitry 1704 to manage a configuration or operation of the ion implanter 102. As depicted in FIG. 17, for example, the memory 1706 may comprise a settings manager 1720, a model manager 1722, a set of ML models 1724, and a set of setting parameters 1732, among other parts. The ML models 1724 include a control model 702 and an inverted control model 1302, among other ML models. The setting parameters 1732 include one or more control parameters 1734 and process parameters 1736. Additionally, or alternatively, the setting parameters 1732 are stored in a settings database 1740 accessible by the device 1702. Although FIG. 17 depicts the inferencing system 1700 depicted as software elements executing on hardware elements, it may be appreciated that the software elements may be implemented as hardware elements or a combination of software elements and hardware elements as needed for a given set of design constraints. Embodiments are not limited in this context.

The settings manager 1720 generally manages setting parameters 1732 associated with one or more components of the ion implanter 102. The settings manager 1720 may perform one or more change, read, update or delete (CRUD) operations to manage the setting parameters 1732 stored in the settings database 1740 or the memory 1706. The settings manager 1720 may also read setting parameters 1732 from a data source, such as components of the ion implanter 102 or input data from the GUI 1742 of the electronic display 1744. The settings manager 1720 may also write setting parameters 1732 to a data sink, such as components of the ion implanter 102 or as output data for presentation on the GUI 1742 of the electronic display 1744. Read operations may be useful for retrieving a current set of setting parameters 1732 from components of the ion implanter 102 or the GUI 1742 for updating by one or more of the ML models 1724. Write operations may be useful for sending an updated set of setting parameters 1732 from the ML models 1724 to components of the ion implanter 102 or the GUI 1742 of the electronic display 1744. The read and write operations may facilitate automated calibration and tuning of the components of the ion implanter 102, such as during normal PM cycles, pre-PM, post-PM, responsive to lower production yields, or emergency disruptions. The read and write operations may also facilitate design and testing of the components of the ion implanter 102, such as for new applications.

The model manager 1722 generally manages various operations for one or more ML models 1724. The ML models 1724 have access to various setting parameters 1732, including control parameters 716 and process parameters 718. The setting parameters 1732 are stored in the memory 1706 or in the settings database 1740.

In general, a machine learning model is a mathematical representation or algorithmic structure that learns patterns and relationships from data in order to make predictions or take decisions without being explicitly programmed. It is a key component of machine learning, which is a subfield of artificial intelligence. A machine learning model is trained on a dataset containing input data and corresponding output labels or target values. During the training process, the model iteratively adjusts its internal parameters and learns from the data, aiming to minimize the difference between its predictions and the true values. Once trained, the model can be used to make predictions or decisions on new, unseen data. It takes the learned patterns and applies them to the input data to generate output predictions or estimates.

There are various types of machine learning models, each suited to different types of tasks and problem domains. Some common categories of machine learning models include: (1) regression models used to predict continuous numerical values, such as housing prices or stock prices; (2) classification models to classify inputs into different classes or categories based on their features, such as image classification or email spam filtering; (3) clustering models to group similar instances in an unsupervised manner, without prior knowledge of the classes or categories; (4) neural networks comprising interconnected nodes (or neurons) organized into layers, with each node applying functions to the data it receives; and (5) decision trees to represent decisions and their possible consequences as a tree-like structure and are commonly used for classification and regression tasks. These are just a few examples, and there are many other types and variations of machine learning models, each designed to tackle different types of problems and data structures.

The ML models 1724 include a control model 1726. The control model 1726 is a ML model that receives as input one or more control parameters 1734 for the components and predicts one or more process parameters 1736 for the components. Each of the control parameters 1734 corresponds to a hardware or software setting for a component of the ion implanter 102. Examples of control parameters 1734 include without limitation a charge parameter, an energy parameter, an acceleration or deceleration parameter, a dopant and flow parameter, a diluent and flow parameter, a source parameter, an analyzer parameter, a corrector parameter, a suppression parameter, a focus parameter, a scan parameter, a quadrupole lens current parameter, a post-acceleration voltage parameter, and other control parameters 1734. Each of the process parameters 1736 correspond to a beam property for an ion beam generated by the ion implanter. Examples of process parameters include without limitation a beam height parameter, a beam width parameter, full height half maximum (FHHM) parameter, a vertical within device angle (VWIDA) parameter, a VWIDA mean (VWIDAM) parameter, a horizontal within device angle (HWIDA) parameter, a HWIDA mean (HWIDAM) parameter, a standard deviation of VWIDA (VWIDAS) parameter, a standard deviation of HWIDA mean (HWIDAS) parameter, a vertical intensity (VI) parameter, a width (full not half) parameter, a spotscore parameter, an energy parameter, a region of interest (ROI) current parameter, a uniformity parameter, and other process parameters 1736. Embodiments are not limited to these examples.

In one embodiment, for example, the control model 1726 is implemented as a feedforward model. A feedforward model is a type of neural network architecture where information flows through the network in one direction, from the input layer to the output layer, without any loops or cycles. It is called “feedforward” because the data passes through the network sequentially, layer by layer, without any feedback connections. In a feedforward model, the input data is fed into the input layer, and then it propagates forward through one or more hidden layers, where the data is transformed and processed. Finally, the transformed data is outputted by the output layer. Each layer is composed of multiple nodes (also called neurons) that perform calculations on the input data and apply linear or non-linear activation functions. The main purpose of a feedforward model is to map the input data to the desired outputs by learning the appropriate set of weights and biases associated with each node in the network. This learning process is typically accomplished through techniques such as backpropagation, where the model adjusts its parameters based on the difference between its predicted outputs and the ground truth labels. feedforward models are commonly used in various machine learning tasks, including classification, regression, and pattern recognition. In one embodiment, for example, the control model 1726 is a Bayesian linear regression model using an optimizer 1304 as described with reference to FIG. 13.

In one embodiment, the control model 1726 is a feedforward model trained to receive an input control vector and predict an output process vector. An input control vector comprises an ordered list of values representing a set of control parameters 716 for the ion implanter 102. Each element of the input control vector corresponds to a specific value for each of the control parameters 716. The output process vector comprises an ordered list of values representing a set of process parameters 718 for the ion implanter 102 corresponding to the control parameters 716. Each element of the output process vector corresponds to a specific value for each of the process parameters 718.

In one embodiment, the inverted control model 722 is a feedforward model trained to receive an input control vector and predict an output process vector. An input control vector comprises an ordered list of values representing a set of process parameters 718 for the ion implanter 102. Each element of the input control vector corresponds to a specific value for each of the process parameters 718. The output process vector comprises an ordered list of values representing a set of control parameters 716 for the ion implanter 102 corresponding to the process parameters 718. Each element of the output process vector corresponds to a specific value for each of the control parameters 716.

FIG. 18 illustrates a training system 1800. The training system 1800 depicts a training device 1816 suitable to generate a trained ML model 1802 for an inferencing device, such as the device 1702 of the inferencing system 1700. In one embodiment, the training device 1816 executes various ML components 1812 to generate an ML model 1802, such as a control model 1726, a variance model 1728 and/or a 1730 by performing various training, testing, and validation operations. It is worthy to note that the training device 1816 may continuously train and re-train the ML model 1802, with or without testing and validation. The training device 1816 may perform testing and validation, for example, to select hyperparameters which parameterize a starting prior belief.

As depicted in FIG. 18, the training device 1816 includes a processing circuitry 1818 and a set of ML components 1812 to support various AI/ML techniques, such as a data collector 1804, a model trainer 1806, a model evaluator 1808 and a model inferencer 1810.

In general, the data collector 1804 collects data 1814 from one or more data sources to use as training data for the ML model 1802. The data collector 1804 collects different types of data 1814, such as text information, audio information, image information, video information, graphic information, and so forth. The model trainer 1806 receives as input the collected data and uses a portion of the collected data as test data for an AI/ML algorithm to train the ML model 1802. The model evaluator 1808 evaluates and improves the trained ML model 1802 using a portion of the collected data as test data to test the ML model 1802. The model evaluator 1808 also uses feedback information from the deployed ML model 1802. The model inferencer 1810 implements the trained ML model 1802 to receive as input new unseen data, generate one or more inferences on the new data, and output a result such as an alert, a recommendation or other post-solution activity.

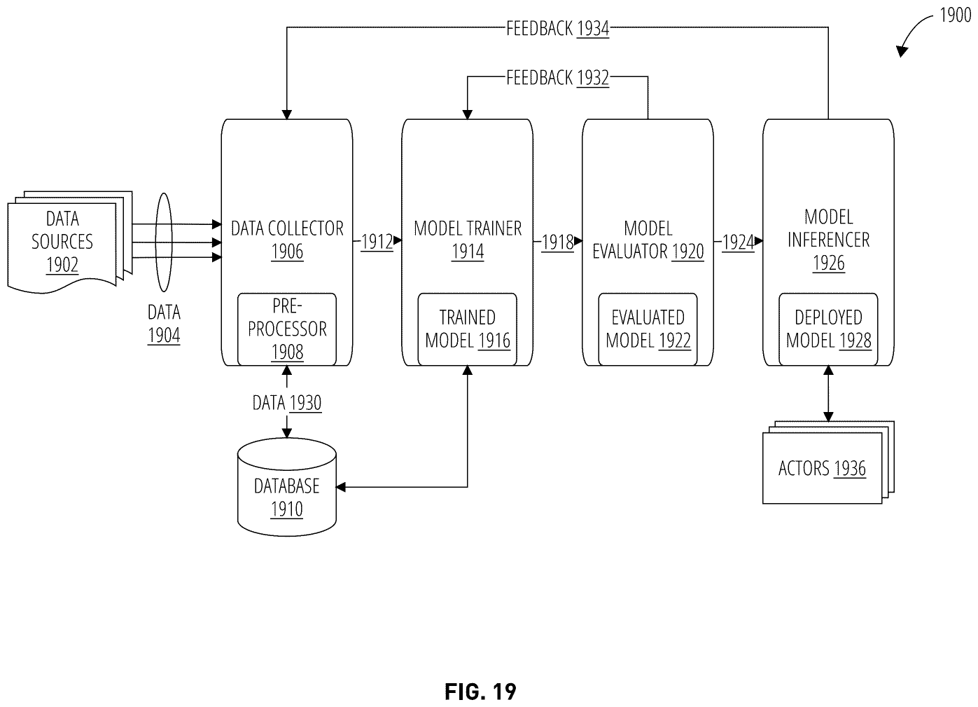

An exemplary AI/ML architecture for the ML components 1812 is described in more detail with reference to FIG. 19.

FIG. 19 illustrates a training system 1900. The training system 1900 is an example of a system suitable for implementing various artificial intelligence (AI) techniques and/or machine learning (ML) techniques to perform various tasks. AI is a science and technology based on principles of cognitive science, computer science and other related disciplines, which deals with the creation of intelligent machines that work and react like humans. AI is used to develop systems that can perform tasks that require human intelligence such as recognizing speech, vision and making decisions. AI can be seen as the ability for a machine or computer to think and learn, rather than just following instructions. ML is a subset of AI that uses algorithms to enable machines to learn from existing data and generate insights or predictions from that data. ML algorithms are used to optimize machine performance in various tasks such as classifying, clustering and forecasting. ML algorithms are used to create ML models that can accurately predict outcomes.

In general, the training system 1900 may include various machine or computer components (e.g., circuit, processor circuit, memory, network interfaces, compute platforms, input/output (I/O) devices, etc.) for an AI/ML system that are designed to work together to create a pipeline that can take in raw data, process it, train a ML model, evaluate its performance, deploy it in a production environment, and continuously monitor and maintain it.

A ML model is a mathematical construct used to predict outcomes based on a set of input data. ML models are trained using large volumes of data, and they can recognize patterns and trends in that data to make accurate predictions. The ML models are derived from different ML algorithms. The ML algorithms may comprise supervised algorithms, unsupervised algorithms, or semi-supervised algorithms. As described herein, the training system 1800 may train an ML model 1802, such as control model 702 and/or inverted control model 1302 using smaller amounts of data relative to other types of ML models.

A supervised algorithm is a type of machine learning algorithm that uses labeled data to train a model. In supervised learning, the algorithm is given a set of input data and corresponding output data, which are used to train the model to make predictions or classifications. The input data is also known as the features, and the output data is known as the target or label. The goal of a supervised algorithm is to learn the relationship between the input features and the target labels, so that it can make accurate predictions or classifications for new, unseen data. Examples of supervised learning algorithms include: (1) linear regression which is a regression algorithm used to predict continuous numeric values, such as stock prices or temperature; (2) logistic regression which is a classification algorithm used to predict binary outcomes, such as whether a customer will churn or not; (3) decision tree which is a classification algorithm used to predict categorical outcomes by creating a decision tree based on the input features; or (4) random forest which is an ensemble algorithm that combines multiple decision trees to make more accurate predictions.

An unsupervised algorithm is a type of machine learning algorithm that is used to find patterns and relationships in a dataset without the need for labeled data. Unlike supervised learning, where the algorithm is provided with labeled training data and learns to make predictions based on that data, unsupervised learning works with unlabeled data and seeks to identify underlying structures or patterns. Unsupervised learning algorithms use a variety of techniques to discover patterns in the data, such as clustering, anomaly detection, and dimensionality reduction. Clustering algorithms group similar data points together, while anomaly detection algorithms identify unusual or unexpected data points. Dimensionality reduction algorithms are used to reduce the number of features in a dataset, making it easier to analyze and visualize. Unsupervised learning has many applications, such as in data mining, pattern recognition, and recommendation systems. It is particularly useful for tasks where labeled data is scarce or difficult to obtain, and where the goal is to gain insights and understanding from the data itself rather than to make predictions based on it.

Semi-supervised learning is a type of machine learning algorithm that combines both labeled and unlabeled data to improve the accuracy of predictions or classifications. In this approach, the algorithm is trained on a small amount of labeled data and a much larger amount of unlabeled data. The main idea behind semi-supervised learning is that labeled data is often scarce and expensive to obtain, whereas unlabeled data is abundant and easy to collect. By leveraging both types of data, semi-supervised learning can achieve higher accuracy and better generalization than either supervised or unsupervised learning alone. In semi-supervised learning, the algorithm first uses the labeled data to learn the underlying structure of the problem. It then uses this knowledge to identify patterns and relationships in the unlabeled data, and to make predictions or classifications based on these patterns. Semi-supervised learning has many applications, such as in speech recognition, natural language processing, and computer vision. It is particularly useful for tasks where labeled data is expensive or time-consuming to obtain, and where the goal is to improve the accuracy of predictions or classifications by leveraging large amounts of unlabeled data.

The training system 1900 may implement various types of ML algorithms including Bayesian linear regression, supervised algorithms, unsupervised algorithms, semi-supervised algorithms, or a combination thereof. A few examples of ML algorithms include support vector machine (SVM), random forests, naive Bayes, K-means clustering, neural networks, and so forth. A SVM is an algorithm that can be used for both classification and regression problems. It works by finding an optimal hyperplane that maximizes the margin between the two classes. Random forests is a type of decision tree algorithm that is used to make predictions based on a set of randomly selected features. Naive Bayes is a probabilistic classifier that makes predictions based on the probability of certain events occurring. K-Means Clustering is an unsupervised learning algorithm that groups data points into clusters. Neural networks is a type of machine learning algorithm that is designed to mimic the behavior of neurons in the human brain. Other examples of ML algorithms include an artificial neural network (ANN), convolutional neural network (CNN), deep learning, decision tree learning, support-vector machine, regression analysis, Bayesian networks, genetic algorithms, federated learning, distributed artificial intelligence, and various other ML algorithms.

As depicted in FIG. 19, the training system 1900 includes a set of data sources 1902 to source data 1904 for the training system 1900. Data sources 1902 may comprise any device capable generating, processing, storing or managing data 1904 suitable for a ML system. Examples of data sources 1902 include without limitation databases, web scraping, sensors and Internet of Things (IoT) devices, image and video cameras, audio devices, text generators, publicly available databases, private databases, and many other data sources 1902. The data sources 1902 may be remote from the training system 1900 and accessed via a network, local to the training system 1900 an accessed via a network interface, or may be a combination of local and remote data sources 1902.

The data sources 1902 may source difference types of data 1904. For instance, the data 1904 may comprise structured data from relational databases, such as customer profiles, transaction histories, or product inventories. The data 1904 may comprise unstructured data from websites such as customer reviews, news articles, social media posts, or product specifications. The data 1904 may comprise data from temperature sensors, motion detectors, and smart home appliances. The data 1904 may comprise image data from medical images, security footage, or satellite images. The data 1904 may comprise audio data from speech recognition, music recognition, or call centers. The data 1904 may comprise text data from emails, chat logs, customer feedback, news articles or social media posts. The data 1904 may comprise publicly available datasets such as those from government agencies, academic institutions, or research organizations. These are just a few examples of the many sources of data that can be used for ML systems. It is important to note that the quality and quantity of the data is critical for the success of a machine learning project.

The data 1904 can be in different formats such as structured, unstructured or semi-structured data. Structured data refers to data that is organized in a specific format or schema, such as tables or spreadsheets. Structured data has a well-defined set of rules that dictate how the data should be organized and represented, including the data types and relationships between data elements. Unstructured data refers to any data that does not have a predefined or organized format or schema. Unlike structured data, which is organized in a specific way, unstructured data can take various forms, such as text, images, audio, or video. Unstructured data can come from a variety of sources, including social media, emails, sensor data, and website content. Semi-structured data is a type of data that does not fit neatly into the traditional categories of structured and unstructured data. It has some structure but does not conform to the rigid structure of a traditional relational database. Semi-structured data is characterized by the presence of tags or metadata that provide some structure and context for the data.

The data sources 1902 may be communicatively coupled to a data collector 1906. The data collector 1906 gathers relevant data 1904 from the data sources 1902. Once collected, the data collector 1906 may use a pre-processor 1908 to make the data 1904 suitable for analysis. This involves data cleaning, transformation, and feature engineering. Data preprocessing is a critical step in ML as it directly impacts the accuracy and effectiveness of the model. The pre-processor 1908 may receive the data 1904 as input, process the data 1904, and output pre-processed data 1930 for storage in a database 1910. The database 1910 may comprise a hard drive, solid state storage, and/or random access memory.

The data collector 1906 may be communicatively coupled to a model trainer 1914. The model trainer 1914 performs AI/ML model training, validation, and testing which may generate model performance metrics as part of the model testing procedure. The model trainer 1914 may receive the pre-processed data 1930 as input 1912 or via the database 1910. The model trainer 1914 may implement a suitable ML algorithm to train an ML model on the pre-processed data 1930. The training process involves feeding the pre-processed data 1930 into a ML model to form a trained model 1916. The training process adjusts its parameters until it achieves an initial level of satisfactory performance.

The model trainer 1914 may be communicatively coupled to a model evaluator 1920. After a ML model is trained, the trained model 1916 needs to be evaluated to assess its performance. This is done using various metrics such as accuracy, precision, recall, and F1 score. The model trainer 1914 may output the trained model 1916, which is received as input 1912. The model evaluator 1920 receives the trained model 1916, and it initiates an evaluation process to measure performance of the trained model 1916. The evaluation process may include providing feedback 1932 to the model trainer 1914, so that it may re-train the trained model 1916 to improve performance in an iterative manner.

The model evaluator 1920 may be communicatively coupled to a model inferencer 1926. The model inferencer 1926 provides AI/ML model inference output (e.g., predictions or decisions). Once the ML model is trained and evaluated, it can be deployed in a production environment where it can be used to make predictions on new data. The model inferencer 1926 receives the evaluated model 1922 as input 1924. The model inferencer 1926 may use the evaluated model 1922 as a deployed model 1928, which is a final production ML model. The inference output of the deployed model 1928 is use case specific. The model inferencer 1926 may also perform model monitoring and maintenance, which involves continuously monitoring performance of the deployed model 1928 in the production environment and making any necessary updates or modifications to maintain its accuracy and effectiveness. The model inferencer 1926 may provide feedback 1932 to the data collector 1906 to train or re-train the ML model. The feedback 1932 may include model performance feedback information, which may be used for monitoring and improving performance of the deployed model 1928.

The model inferencer 1926 may be implemented by various actors 1936 in the training system 1900. The actors 1936 may use the deployed model 1928 on new data to make inferences or predictions for a given task. The actors 1936 may actually implement the model inferencer 1926, or receive outputs from the model inferencer 1926 in a distributed computing manner. The actors 1936 may trigger actions directed to other entities or to itself. The actors 1936 may provide feedback 1934 to the data collector 1906 via the model inferencer 1926. The feedback 1934 may comprise data needed to derive training data, inference data or to monitor the performance of the AI/ML model and its impact to the network through updating of key performance indicators (KPIs) and performance counters.

The training system 1900 may be applicable to various use cases and solutions for AI/ML tasks, such as the inferencing system 1700 and/or training system 1900. Other use cases and solutions for AI/ML are possible as well, and embodiments are not limited in this context.

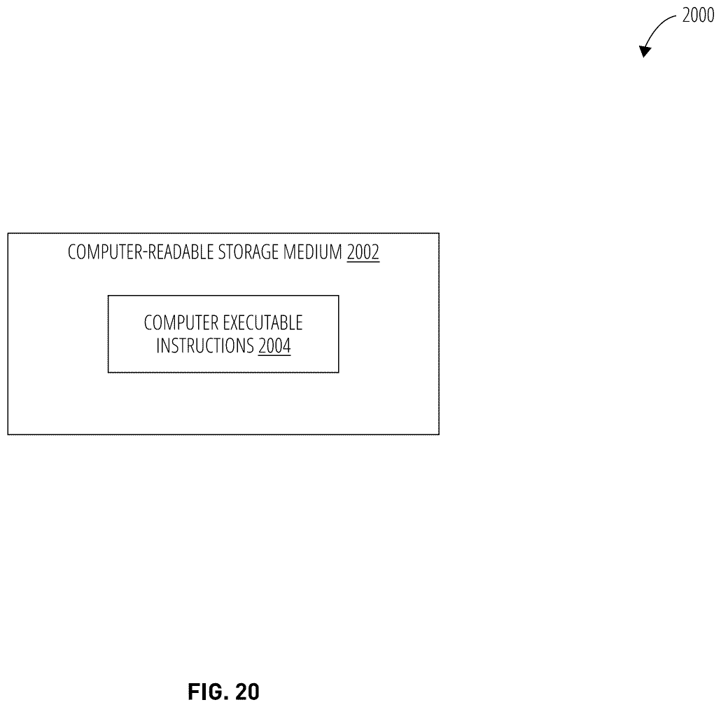

FIG. 20 illustrates an apparatus 2000. Apparatus 2000 may comprise any non-transitory computer-readable storage medium 2002 or machine-readable storage medium, such as an optical, magnetic or semiconductor storage medium. In various embodiments, apparatus 2000 may comprise an article of manufacture or a product. In some embodiments, the computer-readable storage medium 2002 may store computer executable instructions with which circuitry can execute. For example, computer executable instructions 2004 can include instructions to implement operations described with respect to any logic flows described herein. Examples of computer-readable storage medium 2002 or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions 2004 may include any suitable type of code, such as source code, compiled code, interpreted code, executable code, static code, dynamic code, object-oriented code, visual code, and the like.

FIG. 21 illustrates an embodiment of a computing architecture 2100. Computing architecture 2100 is a computer system with multiple processor cores such as a distributed computing system, supercomputer, high-performance computing system, computing cluster, mainframe computer, mini-computer, client-server system, personal computer (PC), workstation, server, portable computer, laptop computer, tablet computer, handheld device such as a personal digital assistant (PDA), or other device for processing, displaying, or transmitting information. Similar embodiments may comprise, e.g., entertainment devices such as a portable music player or a portable video player, a smart phone or other cellular phone, a telephone, a digital video camera, a digital still camera, an external storage device, or the like. Further embodiments implement larger scale server configurations. In other embodiments, the computing architecture 2100 may have a single processor with one core or more than one processor. Note that the term “processor” refers to a processor with a single core or a processor package with multiple processor cores. In at least one embodiment, the computing architecture 2100 is representative of the components of the inferencing system 1700. More generally, the computing architecture 2100 is configured to implement all logic, systems, logic flows, methods, apparatuses, and functionality described herein with reference to previous figures.

As used in this application, the terms “system” and “component” and “module” are intended to refer to a computer-related entity, either hardware, a combination of hardware and software, software, or software in execution, examples of which are provided by the exemplary computing architecture 2100. For example, a component can be, but is not limited to being, a process running on a processor, a processor, a hard disk drive, multiple storage drives (of optical and/or magnetic storage medium), an object, an executable, a thread of execution, a program, and/or a computer. By way of illustration, both an application running on a server and the server can be a component. One or more components can reside within a process and/or thread of execution, and a component can be localized on one computer and/or distributed between two or more computers. Further, components may be communicatively coupled to each other by various types of communications media to coordinate operations. The coordination may involve the uni-directional or bi-directional exchange of information. For instance, the components may communicate information in the form of signals communicated over the communications media. The information can be implemented as signals allocated to various signal lines. In such allocations, each message is a signal. Further embodiments, however, may alternatively employ data messages. Such data messages may be sent across various connections. Exemplary connections include parallel interfaces, serial interfaces, and bus interfaces.

As shown in FIG. 21, computing architecture 2100 comprises a system-on-chip (SoC) 2102 for mounting platform components. System-on-chip (SoC) 2102 is a point-to-point (P2P) interconnect platform that includes a first processor 2104 and a second processor 2106 coupled via a point-to-point interconnect 2170 such as an Ultra Path Interconnect (UPI). In other embodiments, the computing architecture 2100 may be of another bus architecture, such as a multi-drop bus. Furthermore, each of processor 2104 and processor 2106 may be processor packages with multiple processor cores including core(s) 2108 and core(s) 2110, respectively. While the computing architecture 2100 is an example of a two-socket (2S) platform, other embodiments may include more than two sockets or one socket. For example, some embodiments may include a four-socket (4S) platform or an eight-socket (8S) platform. Each socket is a mount for a processor and may have a socket identifier. Note that the term platform may refers to a motherboard with certain components mounted such as the processor 2104 and chipset 2132. Some platforms may include additional components and some platforms may only include sockets to mount the processors and/or the chipset. Furthermore, some platforms may not have sockets (e.g. SoC, or the like). Although depicted as a SoC 2102, one or more of the components of the SoC 2102 may also be included in a single die package, a multi-chip module (MCM), a multi-die package, a chiplet, a bridge, and/or an interposer. Therefore, embodiments are not limited to a SoC.

The processor 2104 and processor 2106 can be any of various commercially available processors, including without limitation an Intel® Celeron®, Core®, Core (2) Duo®, Itanium®, Pentium®, Xeon®, and XScale® processors; AMD® Athlon®, Duron® and Opteron® processors; ARM® application, embedded and secure processors; IBM® and Motorola® DragonBall® and PowerPC® processors; IBM and Sony® Cell processors; and similar processors. Dual microprocessors, multi-core processors, and other multi-processor architectures may also be employed as the processor 2104 and/or processor 2106. Additionally, the processor 2104 need not be identical to processor 2106.

Processor 2104 includes an integrated memory controller (IMC) 2120 and point-to-point (P2P) interface 2124 and P2P interface 2128. Similarly, the processor 2106 includes an IMC 2122 as well as P2P interface 2126 and P2P interface 2130. IMC 2120 and IMC 2122 couple the processor 2104 and processor 2106, respectively, to respective memories (e.g., memory 2116 and memory 2118). Memory 2116 and memory 2118 may be portions of the main memory (e.g., a dynamic random-access memory (DRAM)) for the platform such as double data rate type 4 (DDR4) or type 5 (DDR5) synchronous DRAM (SDRAM). In the present embodiment, the memory 2116 and the memory 2118 locally attach to the respective processors (i.e., processor 2104 and processor 2106). In other embodiments, the main memory may couple with the processors via a bus and shared memory hub. Processor 2104 includes registers 2112 and processor 2106 includes registers 2114.

Computing architecture 2100 includes chipset 2132 coupled to processor 2104 and processor 2106. Furthermore, chipset 2132 can be coupled to storage device 2150, for example, via an interface (I/F) 2138. The I/F 2138 may be, for example, a Peripheral Component Interconnect-enhanced (PCIe) interface, a Compute Express Link® (CXL) interface, or a Universal Chiplet Interconnect Express (UCIe) interface. Storage device 2150 can store instructions executable by circuitry of computing architecture 2100 (e.g., processor 2104, processor 2106, GPU 2148, accelerator 2154, vision processing unit 2156, or the like). For example, storage device 2150 can store instructions for device 1702, devices 1712, devices 1716, or the like.

Processor 2104 couples to the chipset 2132 via P2P interface 2128 and P2P 2134 while processor 2106 couples to the chipset 2132 via P2P interface 2130 and P2P 2136. Direct media interface (DMI) 2176 and DMI 2178 may couple the P2P interface 2128 and the P2P 2134 and the P2P interface 2130 and P2P 2136, respectively. DMI 2176 and DMI 2178 may be a high-speed interconnect that facilitates, e.g., eight Giga Transfers per second (GT/s) such as DMI 3.0. In other embodiments, the processor 2104 and processor 2106 may interconnect via a bus.

The chipset 2132 may comprise a controller hub such as a platform controller hub (PCH). The chipset 2132 may include a system clock to perform clocking functions and include interfaces for an I/O bus such as a universal serial bus (USB), peripheral component interconnects (PCIs), CXL interconnects, UCIe interconnects, interface serial peripheral interconnects (SPIs), integrated interconnects (12Cs), and the like, to facilitate connection of peripheral devices on the platform. In other embodiments, the chipset 2132 may comprise more than one controller hub such as a chipset with a memory controller hub, a graphics controller hub, and an input/output (I/O) controller hub.

In the depicted example, chipset 2132 couples with a trusted platform module (TPM) 2144 and UEFI, BIOS, FLASH circuitry 2146 via I/F 2142. The TPM 2144 is a dedicated microcontroller designed to secure hardware by integrating cryptographic keys into devices. The UEFI, BIOS, FLASH circuitry 2146 may provide pre-boot code.

Furthermore, chipset 2132 includes the I/F 2138 to couple chipset 2132 with a high-performance graphics engine, such as, graphics processing circuitry or a graphics processing unit (GPU) 2148. In other embodiments, the computing architecture 2100 may include a flexible display interface (FDI) (not shown) between the processor 2104 and/or the processor 2106 and the chipset 2132. The FDI interconnects a graphics processor core in one or more of processor 2104 and/or processor 2106 with the chipset 2132.

The computing architecture 2100 is operable to communicate with wired and wireless devices or entities via the network interface (NIC) 180 using the IEEE 802 family of standards, such as wireless devices operatively disposed in wireless communication (e.g., IEEE 802.11 over-the-air modulation techniques). This includes at least Wi-Fi (or Wireless Fidelity), WiMax, and Bluetooth™ wireless technologies, 3G, 4G, LTE wireless technologies, among others. Thus, the communication can be a predefined structure as with a conventional network or simply an ad hoc communication between at least two devices. Wi-Fi networks use radio technologies called IEEE 802.11x (a, b, g, n, ac, ax, etc.) to provide secure, reliable, fast wireless connectivity. A Wi-Fi network can be used to connect computers to each other, to the Internet, and to wired networks (which use IEEE 802.3-related media and functions).

Additionally, accelerator 2154 and/or vision processing unit 2156 can be coupled to chipset 2132 via I/F 2138. The accelerator 2154 is representative of any type of accelerator device (e.g., a data streaming accelerator, cryptographic accelerator, cryptographic co-processor, an offload engine, etc.). One example of an accelerator 2154 is the Intel® Data Streaming Accelerator (DSA). The accelerator 2154 may be a device including circuitry to accelerate copy operations, data encryption, hash value computation, data comparison operations (including comparison of data in memory 2116 and/or memory 2118), and/or data compression. For example, the accelerator 2154 may be a USB device, PCI device, PCIe device, CXL device, UCIe device, and/or an SPI device. The accelerator 2154 can also include circuitry arranged to execute machine learning (ML) related operations (e.g., training, inference, etc.) for ML models. Generally, the accelerator 2154 may be specially designed to perform computationally intensive operations, such as hash value computations, comparison operations, cryptographic operations, and/or compression operations, in a manner that is more efficient than when performed by the processor 2104 or processor 2106. Because the load of the computing architecture 2100 may include hash value computations, comparison operations, cryptographic operations, and/or compression operations, the accelerator 2154 can greatly increase performance of the computing architecture 2100 for these operations.

The accelerator 2154 may include one or more dedicated work queues and one or more shared work queues (each not pictured). Generally, a shared work queue is configured to store descriptors submitted by multiple software entities. The software may be any type of executable code, such as a process, a thread, an application, a virtual machine, a container, a microservice, etc., that share the accelerator 2154. For example, the accelerator 2154 may be shared according to the Single Root I/O virtualization (SR-IOV) architecture and/or the Scalable I/O virtualization (S-IOV) architecture. Embodiments are not limited in these contexts. In some embodiments, software uses an instruction to atomically submit the descriptor to the accelerator 2154 via a non-posted write (e.g., a deferred memory write (DMWr)). One example of an instruction that atomically submits a work descriptor to the shared work queue of the accelerator 2154 is the ENQCMD command or instruction (which may be referred to as “ENQCMD” herein) supported by the Intel® Instruction Set Architecture (ISA). However, any instruction having a descriptor that includes indications of the operation to be performed, a source virtual address for the descriptor, a destination virtual address for a device-specific register of the shared work queue, virtual addresses of parameters, a virtual address of a completion record, and an identifier of an address space of the submitting process is representative of an instruction that atomically submits a work descriptor to the shared work queue of the accelerator 2154. The dedicated work queue may accept job submissions via commands such as the movdir64b instruction.

Various I/O devices 2160 and display 2152 couple to the bus 2172, along with a bus bridge 2158 which couples the bus 2172 to a second bus 2174 and an I/F 2140 that connects the bus 2172 with the chipset 2132. In one embodiment, the second bus 2174 may be a low pin count (LPC) bus. Various devices may couple to the second bus 2174 including, for example, a keyboard 2162, a mouse 2164 and communication devices 2166.

Furthermore, an audio I/O 2168 may couple to second bus 2174. Many of the I/O devices 2160 and communication devices 2166 may reside on the system-on-chip (SoC) 2102 while the keyboard 2162 and the mouse 2164 may be add-on peripherals. In other embodiments, some or all the I/O devices 2160 and communication devices 2166 are add-on peripherals and do not reside on the system-on-chip (SoC) 2102.

The components and features of the devices described above may be implemented using any combination of discrete circuitry, application specific integrated circuits (ASICs), logic gates and/or single chip architectures. Further, the features of the devices may be implemented using microcontrollers, programmable logic arrays and/or microprocessors or any combination of the foregoing where suitably appropriate. It is noted that hardware, firmware and/or software elements may be collectively or individually referred to herein as “logic” or “circuit.”

It will be appreciated that the exemplary devices shown in the block diagrams described above may represent one functionally descriptive example of many potential implementations. Accordingly, division, omission or inclusion of block functions depicted in the accompanying figures does not infer that the hardware components, circuits, software and/or elements for implementing these functions would necessarily be divided, omitted, or included in embodiments.

At least one computer-readable storage medium may include instructions that, when executed, cause a system to perform any of the computer-implemented methods described herein.

Some embodiments may be described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Moreover, unless otherwise noted the features described above are recognized to be usable together in any combination. Thus, any features discussed separately may be employed in combination with each other unless it is noted that the features are incompatible with each other.

With general reference to notations and nomenclature used herein, the detailed descriptions herein may be presented in terms of program procedures executed on a computer or network of computers. These procedural descriptions and representations are used by those skilled in the art to most effectively convey the substance of their work to others skilled in the art.

A procedure is here, and generally, conceived to be a self-consistent sequence of operations leading to a desired result. These operations are those requiring physical manipulations of physical quantities. Usually, though not necessarily, these quantities take the form of electrical, magnetic or optical signals capable of being stored, transferred, combined, compared, and otherwise manipulated. It proves convenient at times, principally for reasons of common usage, to refer to these signals as bits, values, elements, symbols, characters, terms, numbers, or the like. It should be noted, however, that all of these and similar terms are to be associated with the appropriate physical quantities and are merely convenient labels applied to those quantities.

Further, the manipulations performed are often referred to in terms, such as adding or comparing, which are commonly associated with mental operations performed by a human operator. No such capability of a human operator is necessary, or desirable in most cases, in any of the operations described herein, which form part of one or more embodiments. Rather, the operations are machine operations. Useful machines for performing operations of various embodiments include general purpose digital computers or similar devices.

Some embodiments may be described using the expression “coupled” and “connected” along with their derivatives. These terms are not necessarily intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still co-operate or interact with each other.

Various embodiments also relate to apparatus or systems for performing these operations. This apparatus may be specially constructed for the required purpose or it may comprise a general purpose computer as selectively activated or reconfigured by a computer program stored in the computer. The procedures presented herein are not inherently related to a particular computer or other apparatus. Various general purpose machines may be used with programs written in accordance with the teachings herein, or it may prove convenient to construct more specialized apparatus to perform the required method steps. The required structure for a variety of these machines will appear from the description given.

What has been described above includes examples of the disclosed architecture. It is, of course, not possible to describe every conceivable combination of components and/or methodologies, but one of ordinary skill in the art may recognize that many further combinations and permutations are possible. Accordingly, the novel architecture is intended to embrace all such alterations, modifications and variations that fall within the spirit and scope of the appended claims.

The various elements of the devices as previously described with reference to FIGS. 1—may include various hardware elements, software elements, or a combination of both. Examples of hardware elements may include devices, logic devices, components, processors, microprocessors, circuits, processors, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. Examples of software elements may include software components, programs, applications, computer programs, application programs, system programs, software development programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. However, determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores” may be stored on a tangible, machine readable medium and supplied to various customers or manufacturing facilities to load into the fabrication machines that make the logic or processor. Some embodiments may be implemented, for example, using a machine-readable medium or article which may store an instruction or a set of instructions that, if executed by a machine, may cause the machine to perform a method and/or operations in accordance with the embodiments. Such a machine may include, for example, any suitable processing platform, computing platform, computing device, processing device, computing system, processing system, computer, processor, or the like, and may be implemented using any suitable combination of hardware and/or software. The machine-readable medium or article may include, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions may include any suitable type of code, such as source code, compiled code, interpreted code, executable code, static code, dynamic code, encrypted code, and the like, implemented using any suitable high-level, low-level, object-oriented, visual, compiled and/or interpreted programming language.

It will be appreciated that the exemplary devices shown in the block diagrams described above may represent one functionally descriptive example of many potential implementations. Accordingly, division, omission or inclusion of block functions depicted in the accompanying figures does not infer that the hardware components, circuits, software and/or elements for implementing these functions would necessarily be divided, omitted, or included in embodiments.

At least one computer-readable storage medium may include instructions that, when executed, cause a system to perform any of the computer-implemented methods described herein.

Some embodiments may be described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Moreover, unless otherwise noted the features described above are recognized to be usable together in any combination. Thus, any features discussed separately may be employed in combination with each other unless it is noted that the features are incompatible with each other.

It is emphasized that the Abstract of the Disclosure is provided to allow a reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

What is claimed is:

1. A method, comprising:
receiving a set of control parameters representing configurations of multiple tuning segments of a tuning assembly for an ion implanter;
predicting a set of process parameters representing one or more metrics associated with a beam property for an ion beam generated by the ion implanter based on the configurations of the multiple tuning segments using a control model, the control model comprising a forward model using a tuning matrix generated from a set of observations and a prior belief comprising an initial estimate for the tuning matrix and a covariance matrix; and
configuring a set of configurations for the multiple tuning segments based on the set of process parameters, the set of configurations for the multiple tuning segments to cause the ion beam to match a target metric for the ion beam.

2. The method of claim 1, wherein the forward model is an affine function of the tuning matrix and configurations of the multiple tuning segments.

3. The method of claim 1, wherein the tuning matrix comprises a set of profiles, where each profile represents a change in current density values versus configurations on a wafer for a change in configuration of a tuning segment.

4. The method of claim 1, wherein the forward model is a Bayesian linear regression model, further comprising:
initializing the tuning matrix with an approximate prior belief, which contains a mean belief of the tuning matrix, and a corresponding covariance matrix, where each parameter of the tuning matrix comprises a mean belief component and the covariance matrix describes an uncertainty and a relationship between elements of the tuning matrix; and
updating the tuning matrix and the covariance matrix with a new observation using a Bayesian belief update comprising a probability of observation and a probability of a prior belief.

5. The method of claim 3, comprising generating the prior belief covariance matrix using a parameterized physics informed prior belief defined by a set of parameters comprising length scales for wafer and beam configuration correlation, transwafer correlation coefficient, minimum model uncertainty, pointwise uncertainty, observation noise, or width and height of pointwise variances.

6. The method of claim 1, wherein the one or more metrics comprise a current density or an implant angle for the ion beam.

7. An ion implanter, comprising:
an ion source to generate an ion beam;
a tuning assembly comprising multiple tuning segments to control the ion beam;
a control system coupled to the tuning assembly to control a configuration for a tuning segment of the multiple tuning segments, the control system comprising circuitry to:
receive a set of control parameters representing configurations of the multiple tuning segments of the tuning assembly for the ion implanter;
predict a set of process parameters representing one or more metrics associated with a beam property for an ion beam generated by the ion implanter based on the configurations of the multiple tuning segments using a control model, the control model comprising a forward model using a tuning matrix generated from a set of observations and a prior belief comprising an initial estimate for the tuning matrix and a covariance matrix; and
configure the multiple tuning segments based on the set of process parameters to cause the ion beam to match a target metric for the ion beam.

8. The apparatus of claim 7, wherein the tuning matrix comprises a set of tuning profiles, where each tuning profile represents a change in current density values versus configurations on a wafer for a change in configuration of a tuning segment.

9. The apparatus of claim 7, wherein the forward model is a Bayesian linear regression model, the circuitry to:
initializing the tuning and covariance matrices with an approximate prior belief, where each parameter of the tuning matrix represents a mean belief component and a covariance component represents a relationship and certainty of two tuning matrix components; and
updating the tuning and covariance matrices with a new observation using a Bayesian belief update comprising a probability of observation and a probability of a prior belief.

10. The apparatus of claim 7, the circuitry to generate the covariance matrix using a parameterized physics informed prior belief defined by a set of parameters comprising length scales for wafer and beam configuration correlation, transwafer correlation coefficient, minimum model uncertainty, pointwise uncertainty, observation noise, or width and height of pointwise variances.

11. The apparatus of claim 7, wherein the one or more metrics comprise a current density or an implant angle for the ion beam.

12. The apparatus of claim 7, wherein the tuning assembly comprises:
an electrode assembly and the tuning segments comprise a set of rods with at least one rod with a different position relative to the other rods; or
a corrector-bar assembly comprising a set of magnetic core members and the tuning segments comprise a set of coils distributed along the set of magnetic core members with at least one coil with a different current level relative to the other coils.

13. The apparatus of claim 7, the circuitry to cause the ion implanter to generate the ion beam based on the configured multiple tuning segments of the tuning assembly to deliver ions to the silicon wafer.

14. An ion implanter, comprising:
an ion source to generate an ion beam;
a tuning assembly comprising multiple tuning segments to control the ion beam;
a control system coupled to the tuning assembly to control a configuration for a tuning segment of the multiple tuning segments, the control system comprising circuitry to:
receive a set of process parameters representing one or more metrics associated with a beam property for the ion beam generated by the ion implanter;
select a set of control parameters representing configurations of the multiple tuning segments of the tuning assembly for the ion implanter based on the set of process parameters using an inverted control model, the inverted control model comprising a forward model using a tuning matrix generated from a set of observations and a prior belief; and
configure the multiple tuning segments based on the set of control parameters to cause the ion beam to match a target metric for the ion beam.

15. The apparatus of claim 14, wherein the tuning matrix comprises a set of tuning profiles, where each tuning profile represents a change in current density values versus configurations on a wafer for a change in configuration of a tuning segment.

16. The apparatus of claim 14, wherein the forward model is a Bayesian linear regression model, the circuitry to:
initializing the tuning matrix with an approximate prior belief, where each parameter of the tuning matrix represents a mean belief component and a covariance matrix that represents a certainty of the approximate prior belief, and how elements of the tuning matrix are believed to be related to one another; and
updating the approximate prior belief which comprises a tuning matrix mean belief, and its covariance matrix, with a new observation using a Bayesian belief update comprising a probability of observation and a probability of a prior belief.

17. The apparatus of claim 14, the circuitry to generate the covariance matrix using a parameterized physics informed prior belief defined by a set of parameters comprising length scales for wafer and beam configuration correlation, transwafer correlation coefficient, minimum model uncertainty, pointwise uncertainty, observation noise, or width and height of pointwise variances.

18. The apparatus of claim 14, wherein the one or more metrics comprise a current density or an implant angle for the ion beam.

19. The apparatus of claim 14, wherein the tuning assembly comprises:
an electrode assembly and the tuning segments comprise a set of rods with at least one rod with a different position relative to the other rods; or
a corrector-bar assembly comprising a set of magnetic core members and the tuning segments comprise a set of coils distributed along the set of magnetic core members with at least one coil with a different current level relative to the other coils.

20. The apparatus of claim 14, the circuitry to generate the ion beam by the ion implanter based on the configured configurations of the multiple tuning segments of the tuning assembly to deliver ions to a silicon wafer.
